(19) United States
(12) Patent Application Publication
(10) Pub. No.: US 2016/0365154 A1
(43) Pub. Date: Dec. 15, 2016

(54) SEMICONDUCTOR MEMORY DEVICE

(71) Applicant: KABUSHIKI KAISHA TOSHIBA, Tokyo (JP)

(72) Inventors: Yasushi NAGADOMI, Yokohama Kanagawa (JP); Satoru HOSHI, Yokohama Kanagawa (JP)

(21) Appl. No.: 15/060,464

(22) Filed: Mar. 3, 2016

(30) Foreign Application Priority Data
Jun. 12, 2015 (JP) 2015-119512

(51) Int. Cl. G11C 16/26; G11C 16/10; G11C 16/32

(52) U.S. Cl. CPC G11C 16/26; G11C 16/32; G11C 16/10

(57) ABSTRACT

A semiconductor memory device includes a memory cell, a sense amplifier connected to the memory cell, a first data latch that is connected to the sense amplifier and stores data of the memory cell, a second data latch that is connected to the sense amplifier and stores data of the memory cell, a third data latch that is connected to an input/output circuit, a fourth data latch that is connected to the input/output circuit, a first data bus of n-bit width that connects the sense amplifier, the first data latch, and the second data latch, and a second data bus of m-bit width that connects the third data latch and the fourth data latch to the first data bus, where m<n.

### CROSS-REFERENCE TO RELATED APPLICATION

This application is based upon and claims the benefit of priority from Japanese Patent Application No. 2015-119512, filed Jun. 12, 2015, the entire contents of which are incorporated herein by reference.

### FIELD

Embodiments described herein relate generally to a semiconductor memory device.

### BACKGROUND

Generally, a NAND type flash memory in which memory cells are arranged in a three-dimensional manner is known.

### DESCRIPTION OF THE DRAWINGS

FIG. 1 illustrates a block diagram of a memory system according to a first embodiment.

FIG. 2 illustrates a block diagram of a memory device according to the first embodiment.

FIG. 3 illustrates a block of the memory device according to the first embodiment.

FIG. 4 illustrates a block diagram of a sense amplifier module and a page buffer of the memory device according to the first embodiment.

FIG. 5 is schematic diagram that illustrates elements and electrical connections of a part of the sense amplifier module and the page buffer of the memory device according to the first embodiment.

FIG. 6 illustrates distributions of threshold voltages of cell transistors of the memory device according to the first embodiment, before and after two bits are written per cell transistor.

FIG. 7 illustrates a timing chart at the time of writing in the memory system according to the first embodiment.

FIG. 8 illustrates details of address signals which are used in the memory system according to the first embodiment.

FIG. 9 is a conceptual diagram that illustrates an example of a memory space that is recognized by a memory controller according to the first embodiment and an actual memory space of the memory device.

FIG. 10 is an example of address signals necessary for designating an upper page and a lower page.

FIG. 11 illustrates a timing chart at the time of reading in the memory system according to the first embodiment.

FIG. 12 illustrates another timing chart at the time of reading in the memory system according to the first embodiment.

FIG. 13 illustrates a timing chart at the time of writing in a memory system of a comparative example.

FIG. 14 illustrates another timing chart at the time of writing in the memory system of a comparative example.

FIG. 15 is a schematic diagram that illustrates elements and electrical connections of a part of a sense amplifier module and a page buffer of a memory device according to a second embodiment.

FIG. 16 is a schematic diagram that illustrates elements and electrical connection of another part of the sense amplifier module and the page buffer of the memory device according to the second embodiment.

FIG. 17 illustrates a timing chart at the time of writing in a memory system according to the second embodiment.

FIG. 18 illustrates another timing chart at the time of writing in the memory system according to the second embodiment.

FIG. 19 illustrates a timing chart at the time of writing in a memory system of a comparative example.

FIG. 20 illustrates another timing chart at the time of writing in the memory system of a comparative example.

FIG. 21 is a schematic diagram that illustrates elements and electrical connections of a part of a sense amplifier module and a page buffer of a memory device according to a third embodiment.

FIG. 22 is a schematic diagram that illustrates elements and electrical connections of another part of the memory according to the third embodiment.

FIG. 23 illustrates a timing chart at the time of writing in a memory system according to a third embodiment.

FIG. 24 illustrates a timing chart at the time of writing in a memory system for reference.

### DETAILED DESCRIPTION

Embodiments now will be described more fully hereinafter with reference to the accompanying drawings. In the drawings, the thickness of layers and regions may be exaggerated for clarity. Like numbers refer to like elements throughout. As used herein the term “and/or” includes any and all combinations of one or more of the associated listed items and may be abbreviated as “/”.

The terminology used herein is for the purpose of describing particular embodiments only and is not intended to be limiting of the invention. As used herein, the singular forms “a,” “an” and “the” are intended to include plural forms as well, unless the context clearly indicates otherwise. It will be further understood that the terms “comprises,” “comprising,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element such as a layer or region is referred to as being “on” or extending “onto” another element (and/or variations thereof), it may be directly on or extend directly onto the other element or intervening elements may also be present. In contrast, when an element is referred to as being “directly on” or extending “directly onto” another element (and/or variations thereof), there are no intervening elements present. It will also be understood that when an element is referred to as being “connected” or “coupled” to another element (and/or variations thereof), it may be directly connected or coupled to the other element or intervening elements may be present. In contrast, when an element is referred to as being “directly connected” or “directly coupled” to another element (and/or variations thereof), there are no intervening elements present.

It will be understood that, although the terms first, second, etc. may be used herein to describe various elements, components, regions, layers and/or sections, such elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, if the structure in the Figure is turned over, elements described as being on the “backside” of substrate would then be oriented on “upper” surface of the substrate. The exemplary term “upper”, may therefore, encompasses both an orientation of “lower” and “upper,” depending on the particular orientation of the figure. Similarly, if the structure in one of the figures is turned over, elements described as “below” or “beneath” other elements would then be oriented “above” the other elements. The exemplary terms “below” or “beneath” may, therefore, encompass both an orientation of above and below.

Embodiments are described herein with reference to cross section and perspective illustrations that are schematic illustrations of the embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

Embodiments provide a semiconductor memory device whose operation speed is increased.

In general, according to one embodiment, a semiconductor memory device includes a memory cell, a sense amplifier connected to the memory cell, a first data latch that is connected to the sense amplifier and stores data of the memory cell, a second data latch that is connected to the sense amplifier and stores data of the memory cell, a third data latch that is connected to an input/output circuit, a fourth data latch that is connected to the input/output circuit, a first data bus of n-bit width that connects the sense amplifier, the first data latch, and the second data latch, and a second data bus of m-bit width that connects the third data latch and the fourth data latch to the first data bus, where m<n.

Embodiments will be hereinafter described with reference to the drawings. In the following description, the same symbols or reference numerals will be attached to elements having substantially the same function and configuration, and repeated description thereof will be omitted. In addition, all of the description for a certain embodiment may also be applicable to description for other embodiments, unless explicitly excluded.

### First Embodiment

### 1-1. Configuration

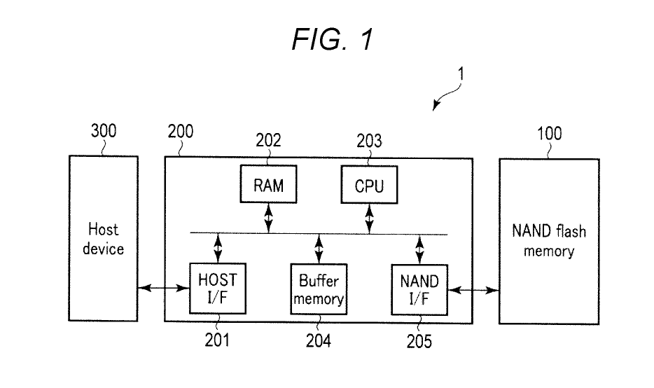

FIG. 1 illustrates a block diagram of a memory system according to a first embodiment. As illustrated in FIG. 1, the memory system 1 includes a NAND type flash memory (memory device, semiconductor memory device) 100, and a memory controller (controller) 200. The memory system 1 may further include a host apparatus 300.

The host apparatus 300 commands the controller 200 to perform an operation of reading from, writing to, or erasing the memory 100, or the like.

The controller 200 controls the memory 100, based on a command from the host apparatus 300. The controller 200 includes a host interface circuit 201, a random access memory (RAM) 202, a central processing unit (CPU) 203, a buffer memory 204, and a NAND interface circuit 205. The host interface circuit 201 is coupled to the host apparatus 300 via a control bus, and is responsible for communication between the controller 200 and the host apparatus 300.

The NAND interface circuit 205 is coupled to the memory 100 via a NAND bus, and is responsible for communication between the controller 200 and the memory 100. The NAND bus includes an I/O bus. The I/O bus has a width of a plurality of bits (for example, eight bits), and transmits signals that contain data, commands, and addresses. In addition, the NAND bus transmits various control signals. The control signals include a ready/busy signal. The ready/busy signal indicates whether the memory 100 is in a ready state or a busy state.

The CPU 203 controls the entire operations of the memory controller 200. The RAM 202 is used as a working area of the CPU 203. The buffer memory 204 temporarily stores data which is transmitted to the memory 100 and data which is transmitted from the memory 100.

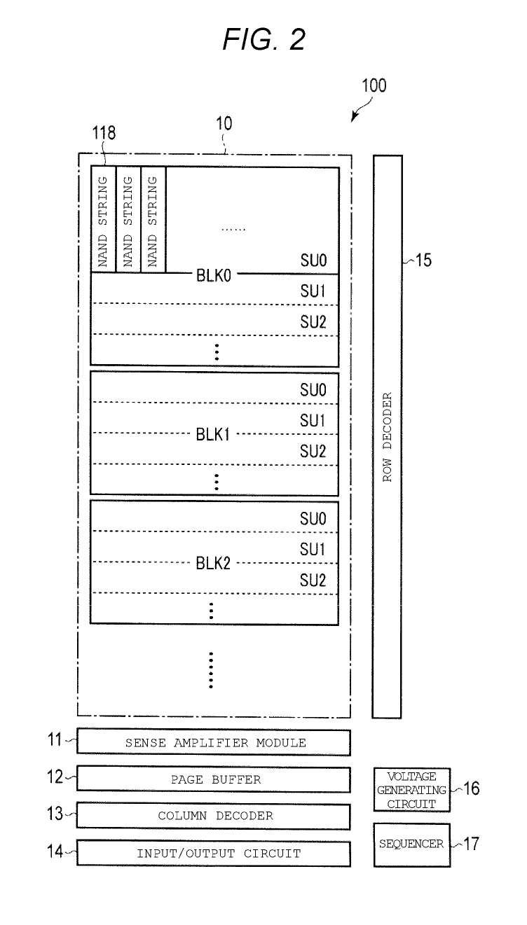

The memory 100 includes a plurality of memory cells, and may store data in a non-volatile manner. For example, the memory 100 includes elements illustrated in FIG. 2. FIG. 2 illustrates a block diagram of the memory device according to the first embodiment. As illustrated in FIG. 2, the memory 100 includes a memory cell array 10, a sense amplifier module 11, a page buffer 12, a column decoder 13, a row decoder 14, an input/output circuit 15, a voltage generating circuit 16, and a sequencer 17.

The memory cell array 10 includes a plurality of (memory) blocks BLK (BLK0, BLK1, BLK2, . . . ). Each of the blocks BLK includes a plurality of string units SU (SU0, SU1, SU2, . . . ). Each of the string units SU includes a plurality of NAND strings NS. Each of the strings NS includes a plurality of memory cells. The memory cell array 10 includes conductive lines, such as a bit line, and a word line.

The sense amplifier module 11 senses data, or temporarily stores the data.

The page buffer 12 stores read data and write data in units referred to a “page”. The size of one page is, for example, KB, and this example will be used in the following description.

The column decoder 13 receives a column address signal, and controls coupling between a bit line and other elements, based on a column address. The row decoder 14 receives a row address signal, and applies various voltages to the word line, based on a row address.

The input/output circuit 15 is responsible for signal communication between the controller 200 and the memory 100.

The voltage generating circuit 16 includes, for example, a charge pump or the like, and generates voltages (potentials) required for writing, reading, and erasing of data. The voltage generating circuit 16 supplies the generated voltages to the sense amplifier module 11, the page buffer 12, the column decoder 13, the row decoder 14, and the like.

The sequencer 17 controls the entire operations of the memory 100.

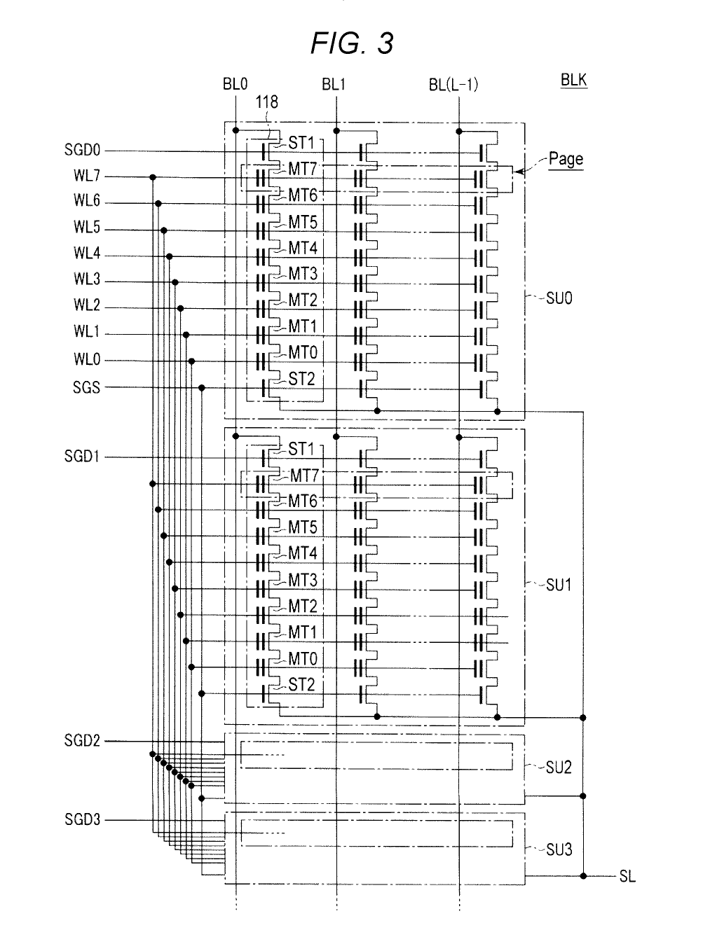

The plurality of blocks BLK includes elements and electrical connections illustrated in, for example, FIG. 3. FIG. 3 illustrates a block of the memory according to the first embodiment. As illustrated in FIG. 3, each of the NAND strings NS includes a plurality of memory cell transistors MT (MT0 to MT7) which are connected in series, and select gate transistors ST1 and ST2. Each of the cell transistors MT stores data in a non-volatile manner. The cell transistors MT are connected in series between ends of one side of the select gate transistors ST1 and ends of one side of the select gate transistor ST2.

Gates of the transistors ST1 included in the string unit SUx (x is zero, or a natural number equal to or larger than “1”) are connected to a select gate line SGDx. Gates of the transistors ST2 are connected in common to a select gate line SGS.

In each of the string units SU, the other end of each transistors ST1 of the plurality of NAND strings NS is connected to one of different bit lines BL (BL0 to BL(k−1)). The symbol K is a natural number, and for example, 16 KB. Each of the bit lines BL is connected to each of the strings NS of different string units SU.

A control gates of a cell transistor MTm (m is zero or a natural number equal to or less than “7”) of the same block BLK is connected to the word line WLm. Writing and reading of data is collectively performed to and from a set (set of cells) of the cell transistors MT which are connected to one word line WL of one string unit SU. The memory space of the set of the cells includes one or more pages. One page may include a memory space of a part of the cell transistors MT among the set of cells. Data of two or more bits may be stored in one cell transistor MT. When the data of two bits are stored per cell transistor MT, a set of upper bits of each of the cell transistors MT sharing the word line WL of one string unit SU is referred to as an upper page, and a set of lower bits is referred to as a lower page.

The memory cell array 10 may have a different configuration. The memory cell array configuration disclosed in, for example, U.S. patent application Ser. No. 12/407,403, filed Mar. 19, 2009, entitled “THREE DIMENSIONAL STACKED NONVOLATILE SEMICONDUCTOR MEMORY” may be employed. In addition, the memory cell array configuration disclosed in U.S. patent application Ser. No. 12/406,524, filed Mar. 18, 2009, entitled “THREE DIMENSIONAL STACKED NONVOLATILE SEMICONDUCTOR MEMORY” may be employed. Furthermore, the memory cell array configurations disclosed in U.S. patent application Ser. No. 12/679,991, filed Mar. 25, 2010, entitled “NON-VOLATILE SEMICONDUCTOR STORAGE DEVICE AND METHOD OF MANUFACTURING THE SAME,” and in U.S. patent application Ser. No. 12/532,030, filed Mar. 23, 2009, entitled “SEMICONDUCTOR MEMORY INCLUDING THREE-DIMENSIONALLY ARRANGED MEMORY CELLS AND METHOD FOR MANUFACTURING SAME” may be employed. The entire contents of the above patent applications are incorporated in the present specification by reference.

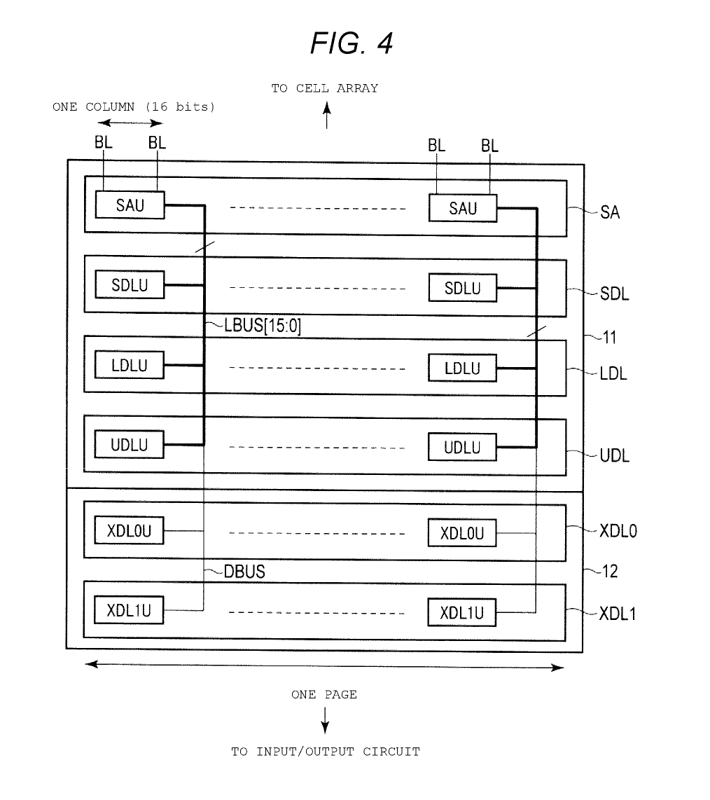

The sense amplifier module 11 and the page buffer 12 have elements and electrical connections illustrated in, for example, FIG. 4. FIG. 4 is a schematic diagram that illustrates the sense amplifier module and the page buffer according to the first embodiment. As illustrated in FIG. 4, the sense amplifier module 11 includes a sense amplifier SA. The sense amplifier SA is connected to the bit line BL, and either senses the read data on the bit line BL, or transmits write data to the bit line BL. The sense amplifier SA may perform sensing or transmitting of data by a size of one page. The sense amplifier SA includes a plurality of sense amplifier groups SAU. Each sense amplifier group SAU senses or transmits data having a plurality of bits (for example, 16 bits. This example will be used in the following description).

The sense amplifier module 11 further includes data latches SDL, LDL, and UDL. The data latches SDL, LDL, and UDL may each store data with a size of one page. The data latch SDL includes a plurality of data latch groups SDLU. Each data latch group SDLU may store data having a plurality of bits (for example, 16 bits). In the same manner, the data latch UDL includes a plurality of data latch groups UDLU. Each data latch group UDLU may store data having a plurality of bits (for example, 16 bits). Furthermore, the data latch LDL also includes a plurality of data latch groups LDLU. Each data latch group LDLU may store data having a plurality of bits (for example, 16 bits).

The page buffer 12 includes two data latches XDL0 and XDL1. The data latches XDL0 and XDL1 may each store data with a size of one page. For example, the data latch XDL0 includes a plurality of data latch groups XDL0U. Each data latch group XDL0U may store data having with a plurality of bits (for example, 16 bits). The data latch XDL1 includes a plurality of data latch groups XDL1U. Each data latch group XDL1U may store data having a plurality of bits (for example, 16 bits).

One sense amplifier group SAU, one data latch group SDLU, one data latch group LDLU, and one data latch group UDLU are connected to each other by a data bus LBUS. The data bus LBUS has a width of 16 bits. For this reason, the data latch group SDLU, the data latch group LDLU, and the data latch group UDLU may transmit and receive in parallel bits of 16-bit data to and from each other.

The one sense amplifier group SAU, the one data latch group SDLU, the one data latch group LDLU, and the one data latch group UDLU are connected to the one data latch group XDL0 and the one data latch group XDL1 by a data bus DBUS. The data bus DBUS has a width of 1 bit. For this reason, the data latch groups SDLU, LDLU, and UDLU transmit and receive the data one bit at a time to and from the data latch group XDL0. In the same manner, the data latch groups SDLU, LDLU, and UDLU transmit and receive the data one bit at a time to and from the data latch group XDL1.

The sense amplifier group SAU, and the data latch groups SDLU, LDLU, UDLU, XDL0U, and XDL1U which are connected by the data buses LBUS and DBUS form one set. By the set of sense amplifier group SAU, and the data latch groups SDLU, LDLU, UDLU, XDL0U, and XDL1U, the data having 16 bits is handled.

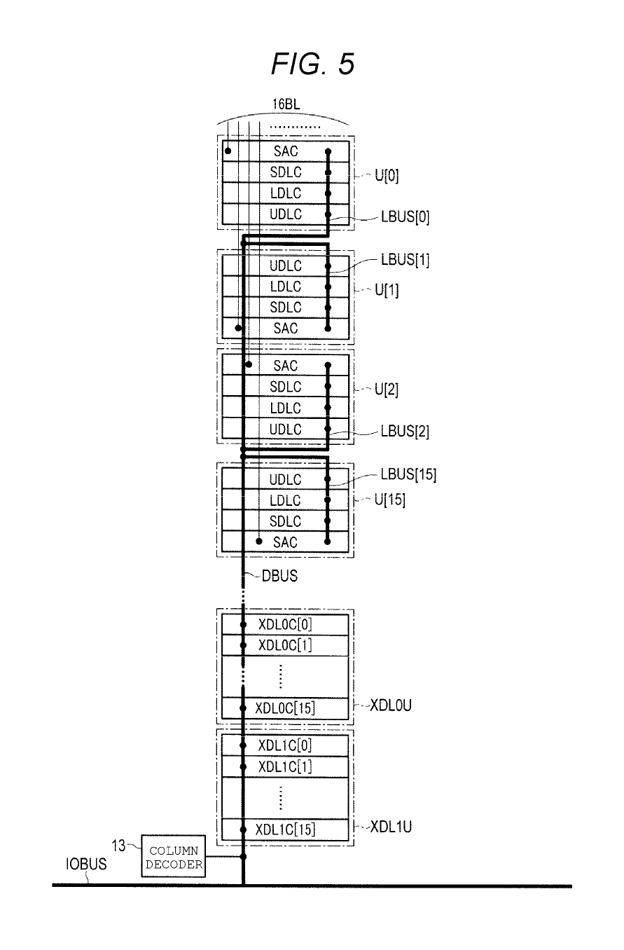

The sense amplifier group SAU, and the data latch groups SDLU, LDLU, UDLU, XDL0U, and XDL1U have elements and electrical connections which are illustrated in FIG. 5. FIG. 5 illustrates elements and electrical connections of one set of the sense amplifier group SAU, and the data latch groups SDLU, LDLU, UDLU, XDL0U, and XDL1U.

The set of the sense amplifier group SAU, and the data latch groups SDLU, LDLU, and UDLU include 16 units U (U[0] to U[15]).

Each unit U is connected to one bit line BL, and includes one sense amplifier circuit SAC, one data latch circuit SDLC, one data latch circuit LDLC, and one data latch circuit UDLC. The one sense amplifier circuit SAC senses read data on the bit line BL, or transmits write data to the bit line BL. The one data latch circuits SDLC, LDLC, and UDLC respectively store data with one bit. In the unit U[n] (n is zero or a natural number equal to or less than “15”), the one sense amplifier circuit SAC and the one data latch circuits SDLC, LDLC, and UDLC may be each connected selectively to the data bus LBUS [n] by transmission gates, and may be connected to each other via the data bus LBUS[n]. The data buses LBUS[0] to LBUS[15] may be all connected selectively to the data bus DBUS.

Each data latch group XDL0U includes data latch circuits XDL0C[0] to XDL0C[15]. Each of the data latch circuits XDL0C[0] to XDL0C[15] may be selectively connected to the data bus DBUS.

Each data latch group XDL1U includes data latch circuits XDL1C[0] to XDL1C[15]. Each of the data latch circuits XDL1C[0] to XDL1C[15] may be selectively connected to the data bus DBUS.

Elements having the same number suffix, e.g., [n], are related to each other, and data is transmitted between these related elements. That is, for example, the data latch circuit XDL0C[0] transmits and receives data to and from the data latch circuits SDLC[0], UDLC[0], and LDLC[0], and the data latch circuit XDL1C[1] transmits and receives data to and from the data latch circuits SDLC[1], UDLC[1], and LDLC[1].

Furthermore, the data bus DBUS is connected to the data bus IOBUS. Electrical connection between the data bus IOBUS and the data bus DBUS is controlled by the column decoder 13. The data bus IOBUS is connected to the input/output circuit 15 of FIG. 2. Write data from the outside of the memory 100 is first received by the data latch XDL0 or XDL1. In the same manner, it is necessary for read data from the cell transistor MT to be transmitted to the data latch XDL0 or XDL1, so as to be output to the outside of the memory 100.

### 1-2. Operation

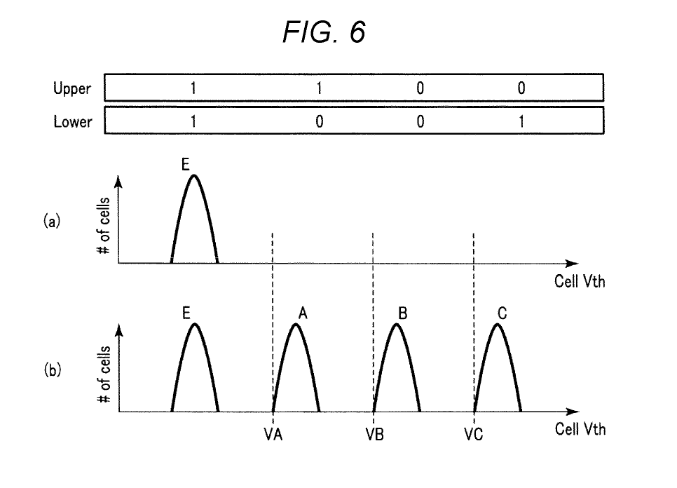

An example of the operation of the memory system 1 according to the first embodiment will be described hereinafter. Operations of the controller 200 and the memory 100 at the time of writing and reading, among various operations of the memory system 1, will be described. The following description is made based on storing of two-bit data per cell transistor MT. Hence, a method of storing the two-bit data per cell transistor MT will be first described with reference to FIG. 6. FIG. 6 illustrates distributions of threshold voltages of cell transistors before and after write of two bits per cell transistor.

The threshold voltage of each cell transistor MT is set as any one of four values according to the data to be stored. A plurality of cell transistors MT which store the data with the same two bits may also have threshold voltages different from each other. For this reason, the threshold voltages have distributions. The threshold voltages are referred to as, for example, an E level, an A level, a B level, and a C level. Section (a) of FIG. 6 illustrates a state (erasing state) before data is written. As illustrated in section (a) of FIG. 6, the cell transistor MT is in an “E” level.

Section (b) of FIG. 6 illustrates a state in which data is written. As illustrated in section (b) of FIG. 6, the cell transistor MT is in the E level, the A level, the B level, or the C level. The threshold voltage in the A level is higher than that in the E level. The threshold voltage in the B level is higher than that in the A level. The threshold voltage in the C level is higher than that in the B level.

The four levels relate to four states of data with two bits. An example of the relationship is as follows. The cell transistor MT in E level is handled as in a state in which data of “1” is stored in upper bits and lower bits. The cell transistor MT in A level is handled as in a state in which data of “1” is stored in the upper bits and data of “0” is stored in the lower bits. The cell transistor MT in B level is handled as in a state in which data of “0” is stored in upper bits and lower bits. The cell transistor MT in C level is handled as in a state in which data of “0” is stored in the upper bits and data of “1” is stored in the lower bits.

“Full Sequence Writing” refers to a writing to a state of section (b) of FIG. 6 without transitioning through a state in which only the lower page (lower bit) is written, such as the state shown in section (a) of FIG. 6.

Read includes verification of threshold voltages of each cell transistors MT. For example, the verification of the threshold voltages includes determining whether or not each cell transistor MT of a target of the verification is in any one of the E level, the A level, the B level, and the C level. The verification of the threshold voltage of the cell transistor MT includes comparison of the threshold voltage of the cell transistor MT with read voltages VA, VB, and VC. The voltage VB is higher than the voltage VA, and the voltage VC is higher than the voltage VB.

The cell transistor MT having the threshold voltage lower than the voltage VA is determined to be in the E level. The cell transistor MT having the threshold voltage which is equal to or higher than the voltage VA and is lower than the voltage VB is determined to be in the A level. The cell transistor MT having the threshold voltage which is equal to or higher than the voltage VB and is lower than the voltage VC is determined to be in the B level. The cell transistor MT having the threshold voltage equal to or higher than the voltage VC is determined to be in the C level.

### 1-2-1. Writing

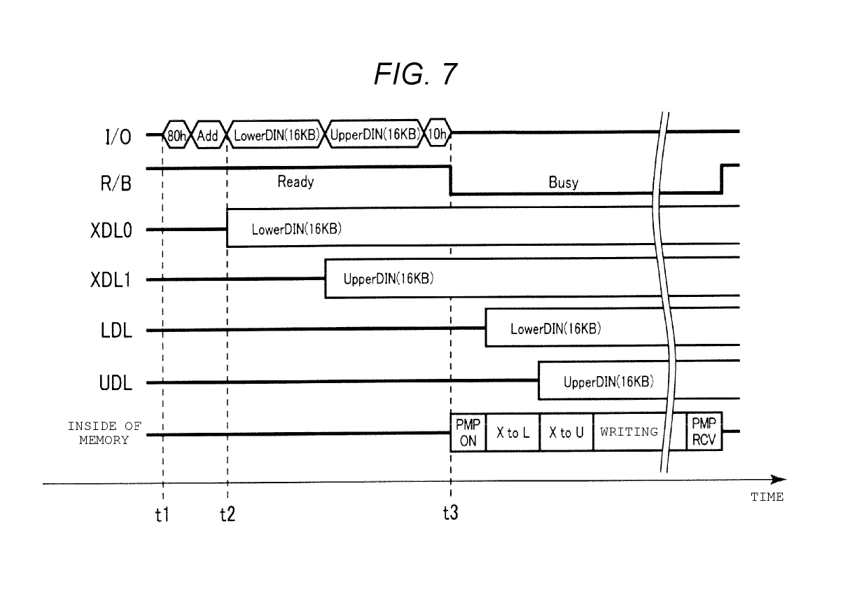

Referring to FIG. 7, an example of operations of the controller 200 and the memory 100 at the time of writing will be described. FIG. 7 illustrates a timing chart at the time of writing according to the first embodiment, and relates to an example of a full sequence writing.

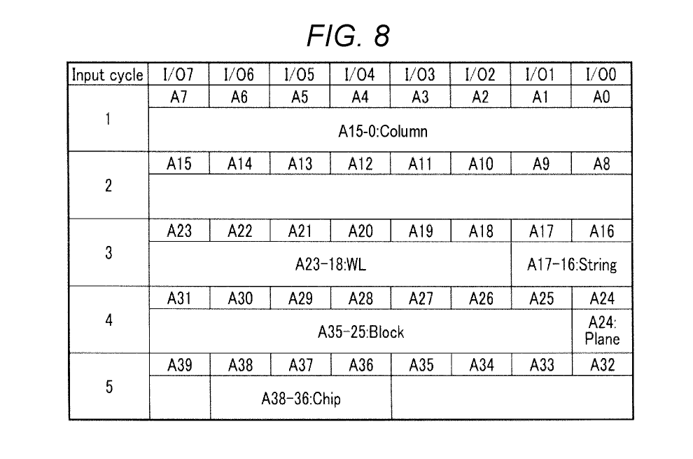

As illustrated in FIG. 7, the controller 200 transmits a write command 80h and an address signal Add via the I/O bus at time t1. The address signal designates two page addresses, to which data is written, in the memory space of the memory 100. The two pages that are a write destination are an upper page and a lower page which are formed by a set of the cell transistors MT connected to one word line WL in one string unit SU. Due to the designation of the two pages, the address signal first designates one block BLK, one string (string unit SU), and one word line WL. Furthermore, the address signal specifies that the write data which is transmitted after the write command has a size of two pages. An example for this method will be described hereinafter with reference to FIG. 8.

FIG. 8 illustrates details of the address signal which is used in the memory system according to the first embodiment. FIG. 8 is based on an example in which the controller 200 and the memory 100 include I/O bus with an eight-bit width and transmit the address signal in five input cycles. In the figure, I/O0 to I/O7 make up the I/O bus, and each of I/O0 to I/O7 transmits data with one bit. Thus, FIG. 8 is based on an example in which the address signal with 40 bits of A0 to A39 is transmitted.

As illustrated in FIG. 8, for example, a column address is transmitted according to each of I/O0 to I/O7 (A0 to A15) of first and second input cycles. The column address designates a column of an access target. One column corresponds to 16 bits which are handled by a set of the sense amplifier group SAU, and the data latch groups SDLU, LDLU, UDLU, XDL0U, and XDL1U illustrated in FIG. 4.

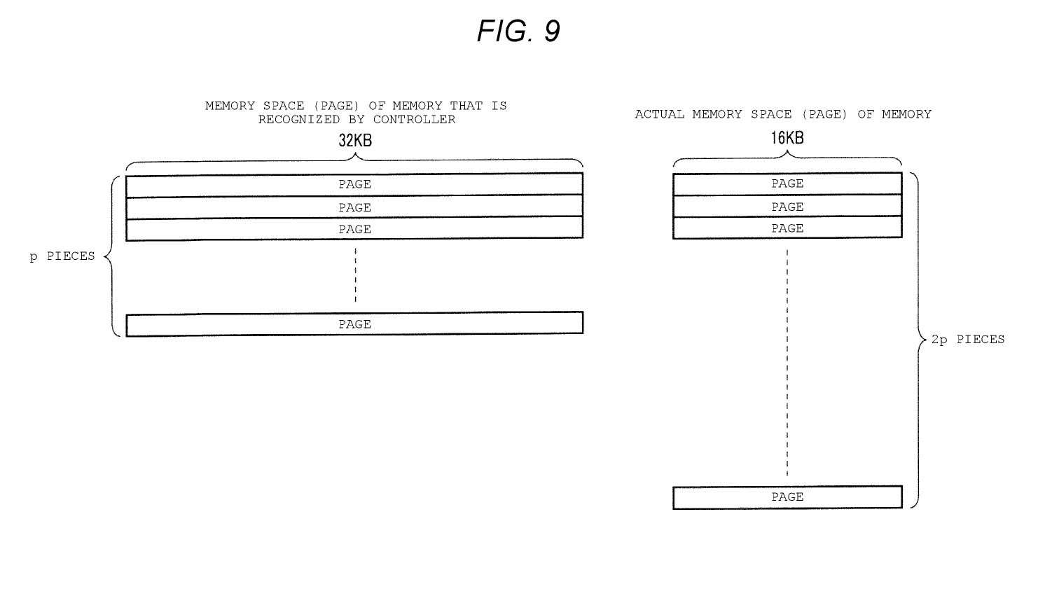

For example, it is possible to specify one column from columns (=2 KB) of double columns (=16 KB/16=1 KB) in one page, according to the column address. This leads the controller 200 to recognize that one page has a double size (=16 KB×2) of a size of actual one page of the memory 100. Thus, when each cell transistor MT stores two bits, the controller 200 recognizes that a set of cell transistors MT connected to one word line WL stores one page which includes a set of the upper page and the lower page formed by the transistors MT. Specifically, as illustrated in FIG. 9, the actual memory space of the memory 100 includes a page with a size of 16 KB of 2p pieces, and in contrast to this, the memory space of the memory 100 which is recognized by the controller 200 includes a page with a size of 32 KB of p pieces. When one write data has a size of one page different from the present embodiment, the column address signal designates a column of a size of one page.

The description returns to FIG. 8. A string address is transmitted according to I/O0 and I/O1 (A16 to A17) of a third input cycle. The string address designates the string (string unit SU) of an access target. In addition, a word line address is transmitted according to I/O2 to I/O7 (A18 to A23) of the third cycle. The word line address designates the word line WL of an access target.

A plane address is transmitted according to I/O0 (A24) of a fourth input cycle. The plane address designates a plane of an access target, when the memory 100 includes a plurality of planes. The plane includes a set of the memory cell array 10, the sense amplifier module 11, the page buffer 12, the column decoder 13, and the row decoder 14.

A block address is transmitted according to I/O1 to I/O7 of the fourth input cycle and I/O0 to I/O3 of a fifth input cycle which are A25 to A35. The block address designates the block BLK of an access target. A chip address is transmitted according to I/O4 to I/O6 (A36 to A38) of the fifth input cycle. The chip address designates the memory 100 of an access target, when the memory system includes a plurality of the memories 100.

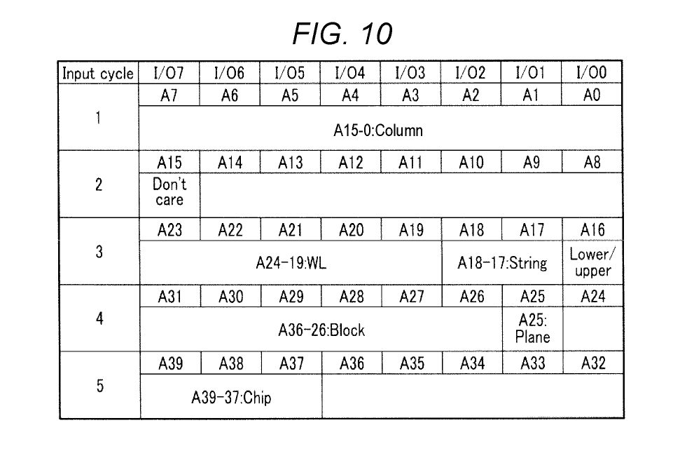

The column address may designate columns of bit numbers equal to the size of two pages, and thus the address signal does not require assignment of bits for designating the upper page or the lower page. In this case, the bit for designating the upper or lower page (for example A16 shown in FIG. 10) is excluded, and subsequent bits (after A17) are shifted to a bit before by one bit. FIG. 10 illustrates an example of an address signal which requires designation of the upper page and the lower page.

Referring back to FIG. 7, the controller 200 transmits data (LowerDIN) to be written to the lower page at time t2 to the memory 100. Furthermore, the controller 200 transmits data (UpperDIN) to be written to the upper page to the memory 100, after the data LowerDIN. The data LowerDIN is stored in one (for example, data latch XDL0; the following description uses this example) of the two data latches XDL0 and XDL1, by the sequencer 17. The data UpperDIN is stored in the other (for example, data latch XDL1; the following description uses this example) of the two data latches XDL0 and XDL1. At a time point in which write starts, the data latches XDL0 and XDL1 do not store any valid data, and may receive write data.

The data LowerDIN and UpperDIN are continuously transmitted, without specifying a boundary between the data LowerDIN and the data UpperDIN (i.e., where the data LowerDIN ends and where the data UpperDIN begins). For this reason, the sequencer 17 starts first to store the received data to the data latch XDL0 as soon as the data is received. When storing of the data with a size of one page in the data latch XDL0 is completed, the sequencer 17 starts to store different data with a size of one page which is subsequent to the received data with a size of one page, in the data latch XDL1, at the same time as a start of reception. Thus, a portion (data LowerDIN) with a size of one page is stored in the data latch XDL0 from the head of the data with a size of two pages, and a subsequent portion (data UpperDIN) with a size of one page is stored in the data latch XDL1. The sequencer 17 recognizes which one of the data latches XDL0 and XDL1 stores the data LowerDIN or UpperDIN.

The controller 200 further transmits a command 10h to the memory 100 after the data UpperDIN. The command 10h instructs a start of full sequence writing. The sequencer 17 recognizes the instruction of the start of the full sequence writing, based on that the command 10h is received by the memory 100. Specifically, the sequencer 17 recognizes that the data with a size of two pages is written by the full sequence writing to a memory space of the set of the cell transistors MT connected to the designated word line WL of the designated string unit SU of the block BLK designated by the address signal Add. When receiving the command 10h, the memory 100 enters a busy state at time t3, and indicates the busy state according to the ready/busy signal R/B.

The full sequence writing includes operations, such as pump setup (PMP ON), data transfer, write, pump recovery, and the like. The pump setup indicates generation of a voltage required for writing, performed by the voltage generating circuit 16, and includes generation of a voltage which is applied to the word line WL and the select gate lines SGD and SGS, and generation of a voltage required for an operation of the data bus DBUS. The pump recovery (PMP RCV) indicates initialization of the voltage generating circuit 16.

The data transfer includes transfer of the data LowerDIN in the data latch XDL0 to one (for example, data latch LDL; the following description uses this example) of the data latches SDL, UDL, and LDL (X to L), and transfer of the data UpperDIN in the data latch XDL1 to another (for example, data latch UDL; the following description uses this example) of the data latches SDL, UDL, and LDL (X to U).

The write includes applying a predetermined potential to the word line WL and the select gate lines SGD and SGS, verifying the written data, and the like. As the result of write, the data is written to the upper page and the lower page which is designated by the address of write destination. That is, the sequencer 17 calculate whether each of the cell transistors connected to the word line (selected word line) selected (designated) by the data LowerDIN and UpperDIN has to be maintained to the E level, or has to be written to any one of the A level, the B level, and the C level. Subsequently, the sequencer 17 maintains each cell transistor MT connected to the selected word line WL to the E level with using a control of the sense amplifier module 11 and the row decoder 14, or sets each cell transistor MT to a threshold voltage of the A, B, or C level. When the write and verification of data is completed, the sequencer 17 performs the pump recovery. When the pump recovery is completed, the sequencer 17 indicates the ready state according to the ready/busy signal R/B. Thus, the write operation which is performed by the controller 200 and the memory 100 is completed.

### 1-2-2. Reading

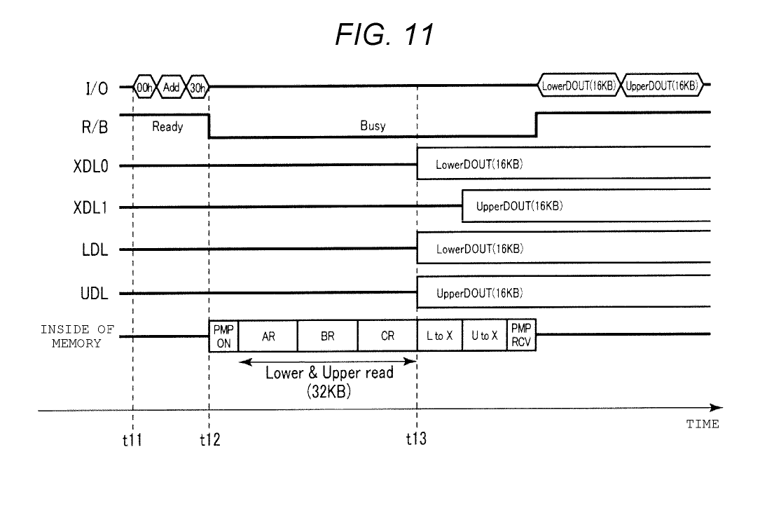

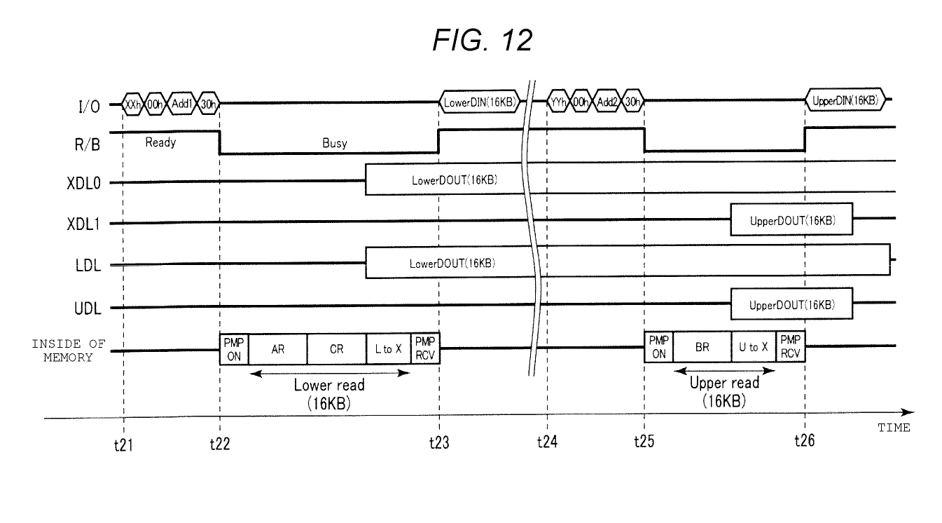

Referring to FIG. 11 and FIG. 12, an example of the operations of the controller 200 and the memory 100 at the time of reading will be described. FIG. 11 and FIG. 12 illustrate timing charts at the time of reading the memory system according to the first embodiment.

The reading includes two methods. In the first reading method, both the upper page and the lower page in a memory space of a set of the cell transistor MT connected to one word line WL are designated by one set of commands. In the second reading method, only the upper page or only the lower page in a memory space of a set of the cell transistor MT connected to one word line WL is designated by one set of commands. FIG. 11 is based on an example of the first reading method, and FIG. 12 is based on an example of the second reading method.

In the first reading method, as illustrated in FIG. 11, the controller 200 transmits a reading command 00h and the address signal Add to the memory 100 at time t11. The command 00h indicates reading from the cell transistor MT connected to the word line WL designated by a subsequent address signal Add. In the same manner as writing, the address signal Add designates at least one of the columns of a size of two pages using the column address (refer to FIG. 8). Subsequently, the controller 200 transmits a command 30h to the memory 100. The command 30h indicates a start of reading.

When the memory 100 receives the command 30h, the sequencer 17 performs the pump setup at time t12, and subsequently, performs reading. The reading includes applying a predetermined potential to the word line WL and the select gate lines SGD and SGS, or the like. The reading includes verification of the threshold voltage of each cell transistor MT (of reading target) connected to the designated word line WL.

FIG. 11 illustrates an example of verification of the sequence of the A level, the B level, and the C level. First of all, the sequencer 17 determines whether or not the cell transistor MT of a reading target has a threshold voltage equal to or higher than the voltage VA (A reading (AR)). The cell transistor MT having a threshold voltage lower than the voltage VA is determined to be in the E level. Subsequently, the sequencer 17 determines whether or not the cell transistor (cell transistor of B reading target) MT excluding the cell transistor which is calculated as in the E level among the cell transistors MT of all the reading targets has a threshold voltage equal to or higher than the voltage VB (B reading (BR)). The cell transistor MT having a threshold voltage lower than the voltage VB among the cell transistors MT of the B reading target is determined to be in the A level.

In the same manner, the sequencer 17 determines whether or not the cell transistor (cell transistor of C reading target) MT excluding the cell transistor MT which is calculated as in the E or A level among the cell transistors MT of all the reading targets has a threshold voltage equal to or higher than the voltage VC (C reading (CR)). The cell transistor MT having a threshold voltage lower than the voltage VC among the cell transistors MT of the C reading target is determined to be in the B level, and the cell transistor MT having a threshold voltage equal to or higher than the voltage VC is determined to be in the C level.

The sequencer 17 produces read data (LowerDOUT) of the lower page and read data (UpperDOUT) of the upper page, using the threshold voltage levels of the cell transistors MT. The data LowerDOUT includes a set of values of lower bits of each cell transistor MT among the set of the cell transistors MT of reading target. The data UpperDOUT includes a set of values of higher bits of each cell transistor MT among the set of the cell transistors MT of reading target. The data LowerDOUT is stored in, for example, the data latch LDL. The data UpperDOUT is stored in, for example, the data latch UDL.

Subsequently, the sequencer 17 transmits the data LowerDOUT in the data latch LDL to one (for example, XDL0; the following description uses this example) of the two data latches XDL0 and XDL1, at time t13. Furthermore, the sequencer 17 transmits the data UpperDOUT in the data latch UDL to the other (for example, XDL1; the following description uses this example) of the two data latches XDL0 and XDL1. The data LowerDOUT and UpperDOUT in the data latches XDL0 and XDL1 is transmitted to the controller 200 according to the control of the sequencer 17. Subsequently, the sequencer 17 performs the pump recovery, and completes the reading.

In the second reading method, as illustrated in FIG. 12, the controller 200 transmits a prefix command XXh or YYh before the reading command 00h to the memory 100. The prefix command XXh indicates that the reading command 00h instructs reading from the lower page subsequently. The prefix command YYh indicates that the reading command 00h instructs reading from the upper page subsequently.

When receiving the command XXh or 00h, the memory 100 reads data from the lower page of the set of the cell transistors MT designated by the subsequent address signal Add1. Details of the data read from the lower page become different depending on assignment of values to a certain level, higher bits, and lower bits. An example based on the example of FIG. 6 is as follows. The sequencer 17 performs the A reading and the C reading. As a result of the A and C reading, the cell transistor MT in the E level or the C level is specified. The cell transistor MT in the E level or the C level stores one piece of data in the lower bits. Based on this, the data LowerDOUT of the lower page is generated. The generated data LowerDOUT is stored in, for example, the data latch LDL, then is transmitted to the data latch XDL0, and is transmitted to the controller 200.

Meanwhile, when the commands YYH and 00h are subsequently received, the memory 100 reads data from the upper page of the set of the cell transistors MT designated by the subsequent address signal Add2. Details of the data read from the upper page become different depending on assignment of values to a certain level, higher bits, and lower bits. An example based on the example of FIG. 6 is as follows. The sequencer 17 performs the B reading. As a result of the B reading, the cell transistor MT in the E level or the A level is specified. The cell transistor MT in the E level or the A level stores one piece of data in the higher bits. Based on this, the data UpperDOUT of the upper page is generated. The generated data UpperDOUT is stored in, for example, the data latch UDL, then is transmitted to the data latch XDL1, and is transmitted to the controller 200.

The reading the upper page or the lower page corresponds to the reading the first half or the second half of the page of a size of 16 KB×2 of the set of the cell transistors MT connected to the word line WL designated by the controller 200.

### 1-3. Effect (Advantage)

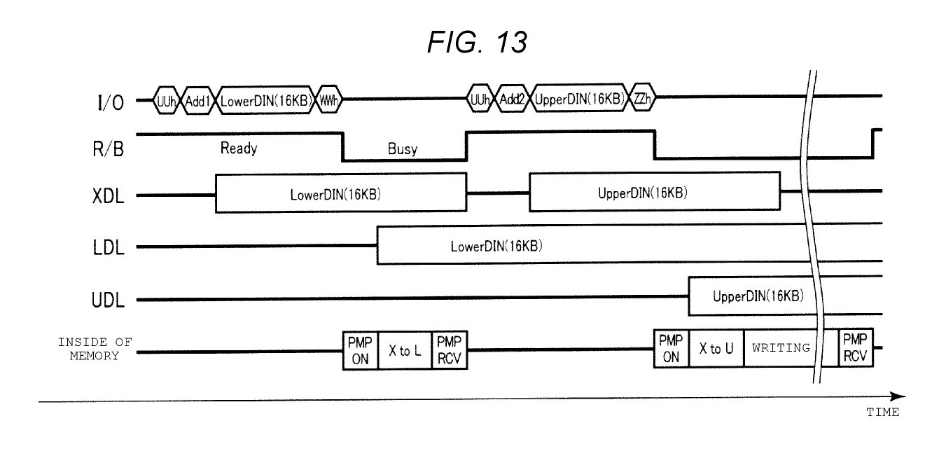

According to the first embodiment, the following effects are obtained. First of all, for comparison, an example of the full sequence writing to the memory having only one data latch (for example, data latch XDL) for input/output of the data to and from the memory will be described with reference to FIG. 13. As illustrated in FIG. 13, the controller transmits a write command UUh, the address signal Add1, the data LowerDIN, and a command WWh to the memory. The address signal Add1 designates a block, a string, a word line, and the upper page or the lower page. The received data LowerDIN is stored in the data latch XDL. The command WWh indicates that data of one page is transmitted. When the command WWh is received, the memory performs the pump setup, transmits the data LowerDIN to the data latch (for example, data latch LDL) (X to L), and performs the pump recovery. After transmission of the data LowerDIN is completed, the data latch XDL may receive data again.

When the memory is in a ready state, the controller transmits a write command UUh, the address signal Add2, the data UpperDIN, and a command ZZh to the memory. The received data LowerDIN is stored in the data latch XDL. The command ZZh indicates a start of the full sequence writing. The memory receives the command ZZh, performs the pump setup, and transmits the data UpperDIN to the data latch (for example, data latch UDL) (X to U). As a result, a start of the full sequence writing is ready, and then memory performs the full sequence writing.

Meanwhile, according to the first embodiment, the memory 100 includes the two data latches XDL0 and XDL1 connected to the data bus IOBUS. For this reason, the memory 100 does not require transmission to a data latch (data latch LDL or UDL, or the like) different from the data latches XDL0 or XDL1, and may store the data of two pages in the data latches XDL0 and XDL1. Thus, the memory 100 may continuously (in response to one write command) receive the data of two pages for the full sequence writing. This eliminates the need for transmission of the write command UUh twice, as illustrated in a comparison example of FIG. 13. As a result, as may be apparent from the comparison with FIG. 13, the first embodiment only requires the pump setup of one time and the pump recovery of one time. As a result, the time required for the full sequence writing according to the first embodiment is reduced, as compared with that of the example of FIG. 13.

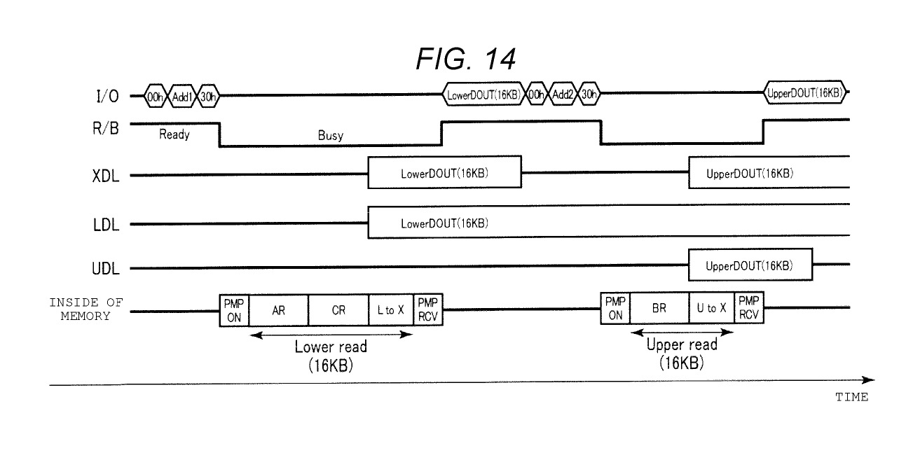

The same effects may also be obtained from the reading. That is, in the continuous reading of two pages of the controller and the memory of the example for comparison, two read commands 00h are not required to be transmitted, as illustrated in FIG. 14. For this reason, the pump setup and the pump recovery are required for each of the lower page reading and the upper page reading.

Meanwhile, according to the first embodiment, the pump setup and the pump recovery need to be performed only one time for reading of two pages, as may be seen from FIG. 11. For this reason, the time required for the continuous reading of two pages according to the first embodiment is reduced, as compared with that of the example of FIG. 14.

Furthermore, according to the first embodiment, it is possible to read the lower page or the upper page, by the introduction of the prefix commands XXh and YYh. In the reading of three of more continuous pages, instructing the reading of the upper page and the lower page by one write command is more efficient than the reading of FIG. 14. Meanwhile, in the reading of only the upper or lower page, the reading of FIG. 12 is more efficient than the reading of FIG. 11. It is possible to perform both of the two readings, and thus convenience of the memory 100 is increased.

### Second Embodiment

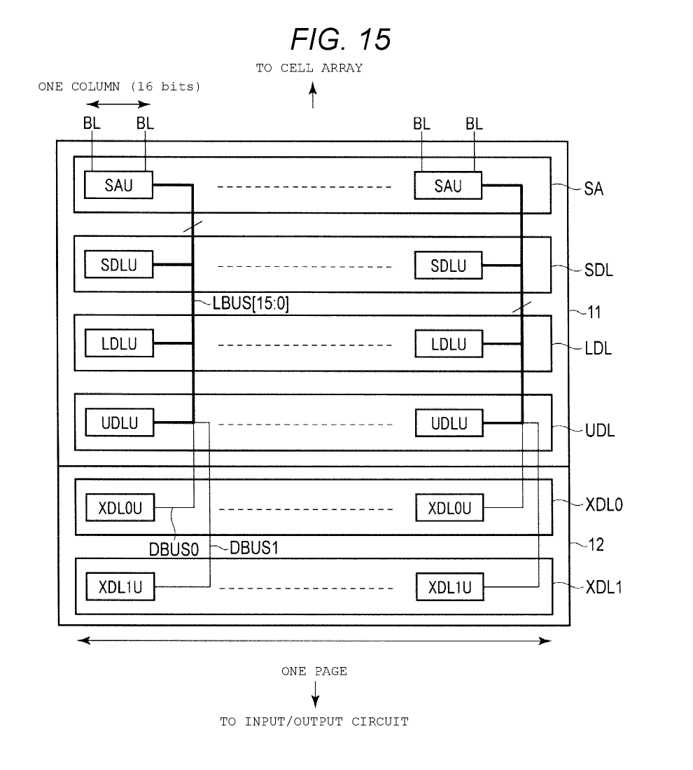

A NAND type flash memory according to a second embodiment will be described with reference to FIG. 15 to FIG. 20.

### 2-1. Configuration

The NAND flash memory according to the second embodiment is different from that of the first embodiment in the configurations of the sense amplifier module 11 and the page buffer 12. The other configurations are the same as those of the first embodiment.

The sense amplifier module 11 and the page buffer 12 according to the second embodiment include elements and electrical connections illustrated in FIG. 15. FIG. 15 is a schematic diagram that illustrates elements and electrical connections of the sense amplifier module 11 and the page buffer 12 according to the second embodiment. As illustrated in FIG. 15, in the second embodiment, one sense amplifier group SAU, one data latch group SDLU, one data latch group LDLU, and one data latch group UDLU are connected to one data latch group XDL0U by a data bus DBUS0, and are connected to one data latch group XDL1U by a data bus DBUS1. The data buses DBUS0 and DBUS1 have widths of one bit.

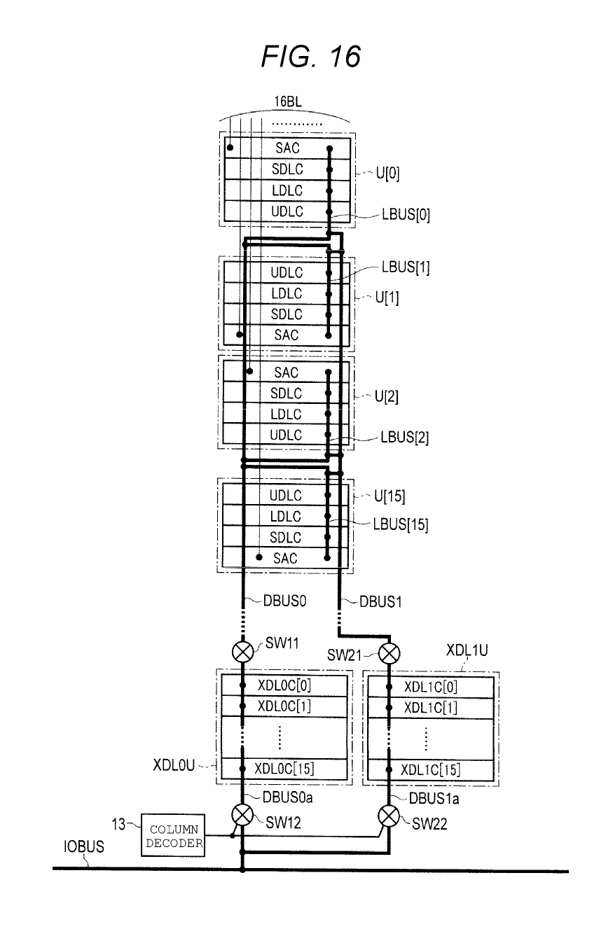

FIG. 16 illustrates details of one sense amplifier group SAU, one data latch group SDLU, one data latch group LDLU, one data latch group UDLU, one data latch group XDL0U, and one data latch group XDL1U.

Data buses LBUS[0] to LBUS[15] may all be selectively connected to the data bus DBUS0, and may all be selectively connected to the data bus DBUS1.

The data bus DBUS0 is connected to a data bus DBUS0a via a switch SW11. The data bus DBUS0a has a width of one bit, and in addition, may be selectively connected to each of data latch circuits XDL0C[0] to XDL0C[15]. The data bus DBUS0a is further connected to the data bus IOBUS via the switch SW12.

The data bus DBUS1 is connected to a data bus DBUS1a via a switch SW21. The data bus DBUS1a has a width of one bit, and in addition, may be selectively connected to each of data latch circuits XDL1C[0] to XDL1C[15]. The data bus DBUS1a is further connected to the data bus IOBUS via the switch SW22.

The switches SW11, SW12, SW21, and SW22 are, for example, metal oxide semiconductor field effect transistors (MOSFET), and are turned on or off by the column decoder 13 and the sequencer 17. The switch SW11 is turned on to electrically connect the data latch XDL0 (that is, the data bus DBUS0a) to the data bus DBUS0 (furthermore, data bus LBUS [0] to LBUS [15])). The switch SW12 is turned on to electrically connect the data bus DBUS0a to the data bus IOBUS. The switch SW21 is turned on to electrically connect the data latch XDL1 (that is, the data bus DBUS1a) to the data bus DBUS1 (furthermore, data bus LBUS[0] to LBUS[15])). The switch SW22 is turned on to electrically connect the data bus DBUS1a to the data bus IOBUS. While one of the switches SW11 and SW21 is turned on, the other is maintained to be off. While one of the switches SW12 and SW22 is turned on, the other is maintained to be off.

### 2-2. Operation

An example of an operation of a memory system 1 according to a second embodiment will be described as follows. Particularly, operations of the controller 200 and the memory 100 at the time of two writings will be described. First writing is normal writing. Second writing is writing in which interrupt processing is included during writing.

### 2-2-1. Example of First Writing

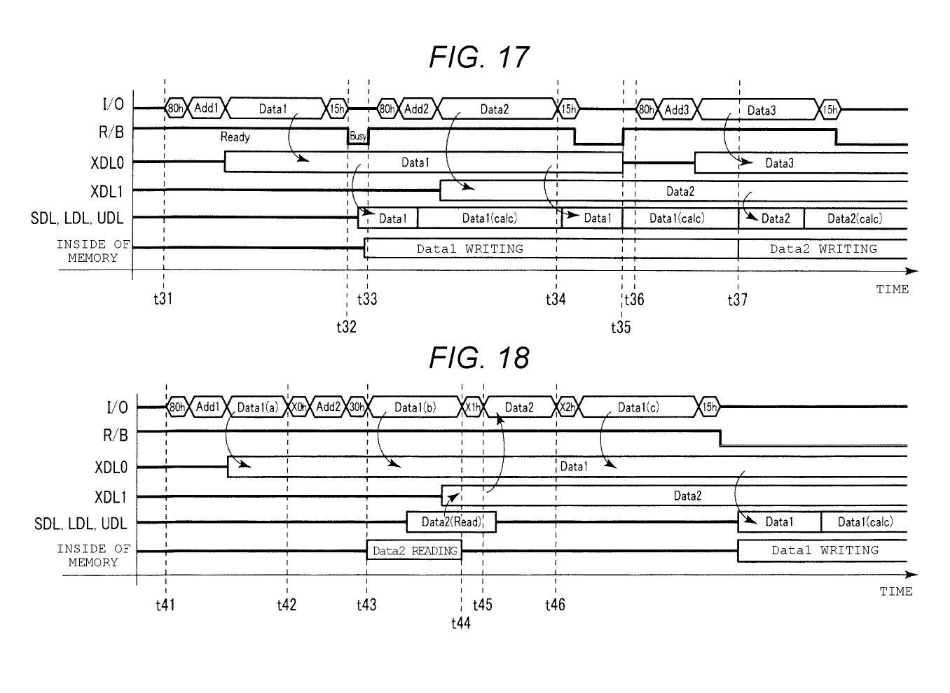

An example of the first writing will be described with reference to FIG. 17. FIG. 17 illustrates a timing chart at the time of writing of the memory system according to the second embodiment. One writing command 80h instructs writing of data with a size of one page, and is based on an example of instruction of continuous writing of a plurality of pages. At the time of a start of writing, both the data latches XDL0 and XDL1 do not store data.

As illustrated in FIG. 17, the controller 200 transmits the write command 80h and the address signal Add1 to the memory 100 via the I/O bus, at time t31. The address signal Add1 designates a write destination of write data Data1 following the address signal Add1, and specifically, designates one word line WL of one string of one block, and the lower page or the upper page. When the data Data1 is received by the memory 100, the data Data1 is stored in a vacant data latch of the data latches XDL0 and XDL1 under a control of the sequencer 17. For example, the data Data1 is stored in the data latch XDL0. When output of the data Data1 is completed, the controller 200 transmits a command 15h to the memory 100. Furthermore, the command 15h indicates presence of the write data.

When the memory 100 receives the command 15h, the sequencer 17 starts writing of the data Data1 at time t32. As a part of this operation, the sequencer 17 performs various calculations using the data Data1 of the data latch XDL0. For performing the calculation, the sequencer 17 transmits the data Data1 of the data latch XDL0 to any one of the data latches SDL, UDL, and LDL. The transmission may be performed several times. The data Data1 in the data latch XDL0 is continuously stored up to time t35. In addition, the data Data1 is continuously written up to time t37, and the data Data1 is written to the designated cell transistor MT.

When the memory 100 receives the command 15h, the memory 100 is in a busy state at time t32, but immediately returns to a ready state at time t33. The data latch XDL0 still stores the data, data transmission from the data latch XDL0 and writing of the data Data1 also continue at time t33, and the memory 100 may further receive the write data from the data latch XDL1.

The controller 200 recognizes that the memory 100 is in a ready state, and transmits the next write command 80h to the memory 100, after time t33. Subsequently, the controller 200 transmits the address signal Add2, the write data Data2, and the command 15h to the memory 100. When the memory 100 receives the data Data2, the data Data2 is stored in a vacant one (the data latch XDL1 in the present example) of the data latches XDL0 and XDL1 under a control of the sequencer 17. When output of the write data Data2 is completed, the controller 200 transmits the command 15h to the memory 100 at time t34. Based on this, the sequencer 17 writes the data Data2 to the designated cell transistor MT at time t37, in the same manner as the data Data1. Also during the writing, the data Data2 is continuously stored in the data latch XDL1.

When the command 15h is received, the memory 100 enters the busy state. The busy state continues until storing of the data Data1 in the data latch XDL0 is completed (time t35). The reason is that the data is stored in the data latches XDL0 and XDL1, and the memory 100 cannot further receive data. When the data latch XDL0 is released at time t35, the memory 100 enters the ready state.

The controller 200 recognizes that the memory 100 is in a ready state, and performs transmission of a command for write data Data3, an address signal Add3, and the data, at time t36. The data Data3 is stored in the data latch XDL0 which completes storing of data at time t35. An operation of the data Data3 at time t36 and thereafter is the same as that of the data Data1 or Data2.

### 2-2-2. Example of Second Writing

An example of second writing will be described with reference to FIG. 18. FIG. 18 illustrates a timing chart at the time of writing of a memory system according to the second embodiment. As illustrated in FIG. 18, the controller 200 transmits the write command 80h, the address signal Add1, and the write data Data1 to the memory 100 at time t41. When the memory 100 starts to receive the data Data1, the sequencer 17 starts to store the write data Data1 in a vacant one (for example, the data latch XDL0; the following description uses this example) of the data latches XDL0 and XDL1.

Subsequently, the controller 200 receives instruction of data reading from, for example, the host apparatus 300, before writing according to the write command 80h is completed. Based on the instruction, the controller 200 stops transmission of the data Data1 at time t42. At a point of time t42, the data latch XDL0 stores part Data1(a) of a head of the write data Data1 which has been already received, and continuously stores the part.

In addition, the controller 200 transmits a read command X0h to the memory 100 at time t42. The read command X0h may be generated before the preceding write command 80h, and the subsequent address signal and a write start command (for example, command 15h) are transmitted. That is, the memory 100 recognizes the read command X0h which is received after the write command 80h is received and before a pair of write start commands 15h is received, as a command which is generated in accordance with a correct sequence.

The controller 200 transmits the address signal Add2 and a read start command 30h to the memory 100 following a command X0h. The address signal Add2 designates an address of a read source.

When the memory 100 receives the command 30h, the sequencer 17 reads the data Data2 from the designated address. The data Data2 is read to any one of the data latches SDL, UDL, and LDL, and furthermore, is transmitted to a vacant one (data latch XDL1, in the present example) of the data latches XDL0 and XDL1 in preparation for output from the memory 100.

The controller 200 recognizes that time is required for preparing output of the read data from the memory 100 after the command 30h is transmitted. Hence, the controller 200 performs a restart of transmission of the write data Data1, using the time for the preparation. Specifically, the controller 200 transmits data Data1(b) to the memory 100 via the I/O bus at time t43 after the command 30h is transmitted. The data Data1(b) is a part following the data Data1(a) of the data Data1. The sequencer 17 recognizes that that data Data1(b) is data of a write target according to the write command 80h and is apart subsequent to the data Data1(a), based on the fact that the write start command 15h pairing with the write command 80h is not yet received. Based on this, the sequencer 17 stores the data Data1(b) in a part following the data Data1(a) of the data latch XDL0.

At time t44 after transmission of the data Data1(b), the controller 200 transmits the command X1h to the memory 100. The command X1h indicates that transmission of a part data (data Data1(b)) of the data Data1 is completed and that transmission of other parts of the data Data1 is not completed. The sequencer 17 recognizes that the data Data2 may be output according to completion of the transmission of the data Data1(b) to the memory 100, based on reception of the command X1h. Based on this, the sequencer 17 transmits the data Data2 of the data latch XDL1 to the controller 200 via the I/O bus, from time t45.

When receiving of the read data Data2 is completed, the controller 200 restarts the transmission of the write data Data1. For this reason, the controller 200 transmits a command X2h to the memory 100 at time t46. The command X2h indicates a start of the transmission of a subsequent data Data1(c), and indicates that the data Data1(c) is a part following the part (data Data1(b)) which is finally transmitted, among the data Data1. The controller 200 transmits the data Data1(c) to the memory 100 according to the command X2h. When the memory 100 receives the data Data1(c), the data Data1(c) is stored in a part following the data Data1(b) of the data latch XDL0 under the control of the sequencer 17. Thus, the write data Data1 is all stored in the data latch XDL0.

When the transmission of the data Data1c is completed, the controller 200 transmits the write start command 15h to the memory 100. When the memory 100 receives the command 15h, the sequencer 17 writes the write data Data1 of the data latch XDL0 to the cell transistor MT designated by the address signal Add1.

FIG. 18 illustrates an example in which the data latch XDL1 also stores the data Data2 after the data Data2 is output. Based on the example, the memory 100 enters the busy state after receiving the command 15h. The reason is that the data latches XDL0 and XDL1 store the data. Thus, after the data Data2 is output, the data latch XDL1 may be released. By doing so, the memory 100 rapidly returns to the ready state after receiving the command 15h, and may perform additional operation using the data latch XDL1.

### 2-2-3. Others

In the configuration of the second embodiment, the operation of the first embodiment may also be performed. That is, at the time of writing, data of an upper page and a lower page for full sequence writing is continuously received by the memory 100 after one write command. At the time reading, one of the data of the upper page and the data of the lower page is stored in one of the data latches XDL0 and XDL1, and the other is stored in the other of the data latches XDL0 and XDL1, in response to one read command.

### 2-3 Effect (Advantage)

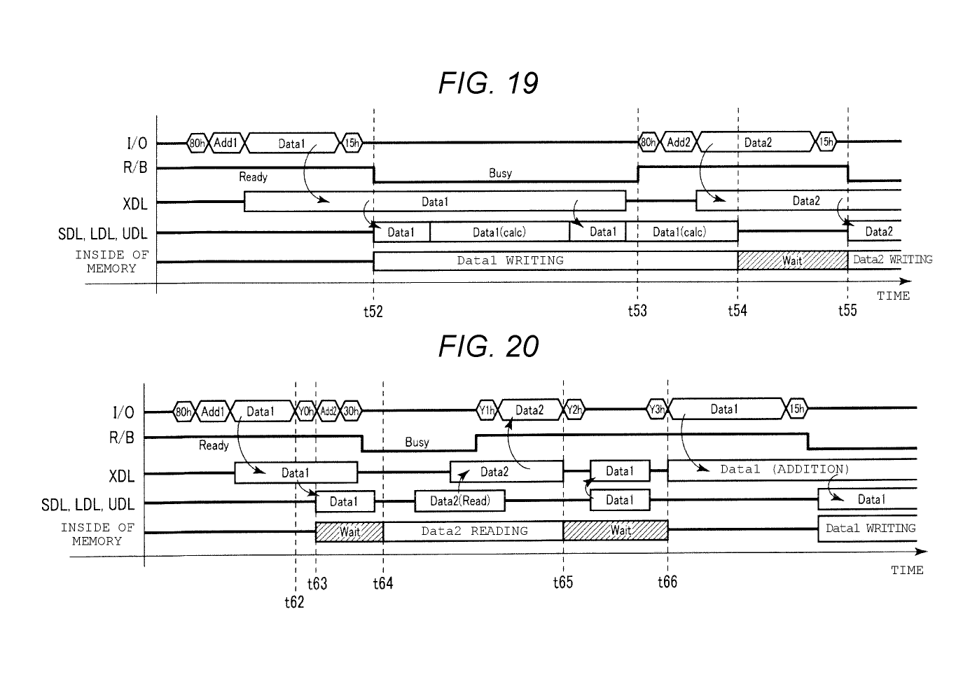

According to the second embodiment, the following effects are obtained. First of all, for comparison, an example of continuous writing to a plurality of pages with respect to a memory having only one data latch (for example, data latch XDL) for input/output will be described with reference to FIG. 19. As illustrated in FIG. 19, when receiving the data Data1 and the command 15h, the memory 100 enters a busy state at time t52. For calculation using the data Data1, a repeated transmission of the data Data1 to the data latches SDL and LDL or UDL is required, and for this reason, the data latch XDL is used by the data Data1. In addition, writing of the data Data1 to the cell transistor starts at time t52.

The controller is required to postpone transmission of the next write command and data, until the data latch XDL is released and thereby the memory enters the ready state. When the need for storing the data Data1 in the data latch XDL disappears and the memory enter the ready state at time t53, the controller transmits the write command 80h, the address signal Add2, and the data Data2 to the memory. When receiving the write data Data2, the memory transmits the data Data2 for writing to the data latches SDL and LDL or UDL and starts writing. However, when a size of the data Data2 is large, a time required for receiving the data Data2 in the data latch XDL may be increased, and a start of transmission to the data latches SDL and LDL, or UDL and a start of writing may be delayed. The transmission and the writing start from time t55.

Meanwhile, writing of the data Data1 is ended at time t54 prior to time t55. For this reason, although the memory may start writing from time t54, the memory has standby time from time t54 to time t55, since preparation for writing of the data Data2 is not completed. The standby time is generated due to the fact that transmission of the write data Data2 from the controller to the memory is postponed.

Meanwhile, according to the second embodiment, the memory 100 includes the two data latches XDL0 and XDL1 which are connected to the data bus IOBUS. For this reason, also while one data latch XDL0 is used by certain data, the memory 100 may receive other data from the controller 200 using the other data latch XDL1. Thus, as may be seen from FIG. 17, after the write start command 15h is received, the memory 100 immediately enters the ready state from time t33, and may receive the next write command 80h and the data Data2. For this reason, at a time point in which writing of the data Data1 is completed from time t37, preparation for writing of the data Data2 is completed. Thus, writing of the data Data2 may be started following the completion of writing of the data Data1. As a result, a time required for continuous writing to a plurality of pages performed by the memory 100 is reduced, as compared with that of FIG. 19.

In addition, interrupt of reading during transmission of the write data to the memory is also the same. First of all, for comparison, an example of interrupt of reading during transmission of the write data with respect to the memory having only one data latch (for example, data latch XDL) for input/output to and from the memory will be described with reference to FIG. 20. As illustrated in FIG. 20, at time t62, when receiving a read command Y0h before all of the write data Data1 is received, the memory performs an operation for releasing the data latch XDL in preparation for the read data. That is, the sequencer transmits a received part of the data Data1 of the data latch XDL to the data latches SDL and LDL, or UDL, from time t63. Since the data latches SDL and LDL, or UDL is used for the transmission, the data cannot be read from the cell transistor of a read source, and a standby time from time t63 to time t64 is generated.

When transmission of the data Data1 is completed, the sequencer starts reading the data Data2 from the cell transistor of a read source at the following time t64. The data Data2 which has been read is transmitted from the data latch XDL to the controller. Subsequently, the sequencer transmits a part of the write data Data1 of the data latches SDL and UDL, or LDL to the data latch XDL, based on the fact that the memory receives the command Y2h. When the transmission is completed, the controller transmits the remaining part of the data Data1 from time t66, after a command Y3h indicating a restart of transmission of the write data Data1 is transmitted.

In this way, transmission of the data Data1 from the data latch XDL and transmission of the data to the data latch XDL are required, and during the transmission, a standby time is generated. Since the data latch XDL and the data latches SDL and LDL, or UDL are connected by the data bus with a width of one bit, data transmission between the data latch XDL and the data latches SDL and LDL, or UDL requires a long time. Thus, operation speed of the memory is decreased due to a plurality of transmissions which require a long time.

Meanwhile, according to the second embodiment, as may be seen from FIG. 18, it is not necessary for the memory 100 to transmit the data Data1(a) of the data latch XDL0 to the data latches SDL and LDL, or UDL, for data reading. For this reason, the memory 100 may start to read the data Data2 from the cell transistors MT, immediately after the read command X0h of interrupt is received. Thus, when reading is instructed during transmission of the write data to the memory, the time required until reading is completed is reduced, as compared with that of FIG. 20.

### Third Embodiment

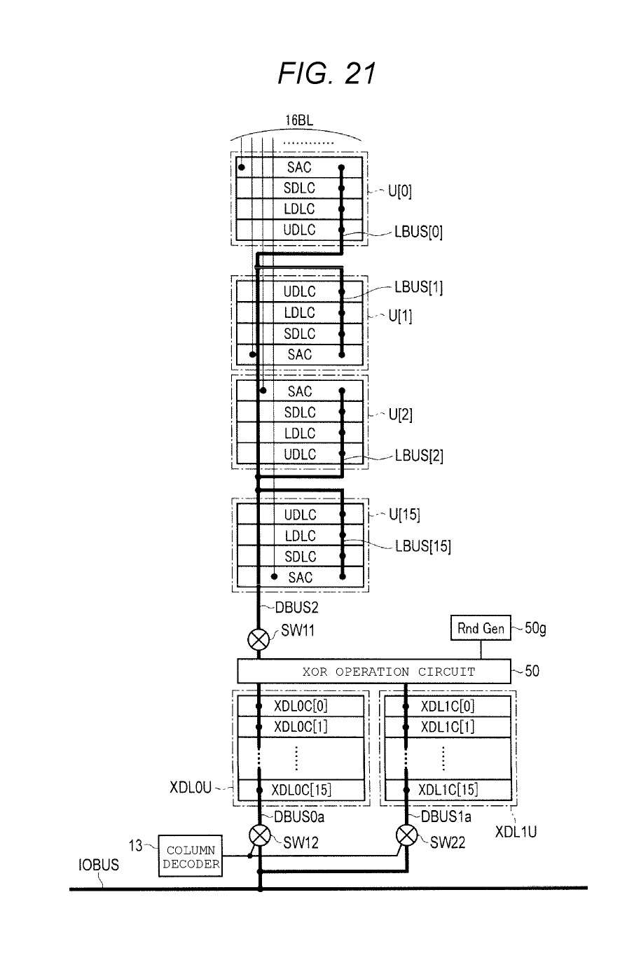

A NAND type flash memory according to a third embodiment will be described with reference to FIG. 21 to FIG. 24. The third embodiment is based on the second embodiment, and the memory 100 further includes an XOR (exclusive logical sum) operation circuit between sense amplifier module 11 and the page buffer 12.

### 3-1. Configuration

The NAND type flash memory according to the third embodiment is different from that of the second embodiment in configurations of the sense amplifier module 11 and the page buffer 12. The other configurations are the same as those of the second embodiment.

The memory 100 includes electrical connections of the sense amplifier module 11 and the page buffer 12 illustrated in FIG. 21, and includes elements and electrical connections illustrated in FIG. 21 between the sense amplifier module 11 and the page buffer 12. FIG. 21 illustrates the sense amplifier module 11, the page buffer 12, and only the portions related to 16 bit lines BL among portions between the sense amplifier module 11 and the page buffer 12. In the same manner as in the first and second embodiments, a configuration illustrated in FIG. 21 is provided with respect to each of a plurality of sets of the 16 bit lines BL.

As illustrated in FIG. 21, the memory 100 further includes an XOR operation circuit 50 and a random number seed generating unit 50g. The XOR operation circuit 50 randomizes the bit positions of the write data (the resulting write data referred to herein as “randomized write data”). In addition, the XOR operation circuit 50 recovers the bit positions of the data received from the cell transistors MT.

An end of a data bus DBUS0a which is opposite to the switch SW12 is connected to the XOR operation circuit 50 instead of the switch SW11 of the second embodiment (FIG. 17). An end of a data bus DBUS1a which is opposite to the switch SW22 is connected to the XOR operation circuit 50 instead of the switch SW21 of the second embodiment. In addition, the XOR operation circuit 50 is connected to a data bus DBUS2 via the switch SW11. The data bus DBUS2 has a width of one bit and may be selectively connected to data buses LBUS [0] to LBUS [15] by a transmission gate. The XOR operation circuit 50 receives a random number seed from the random number seed generating unit 50g.

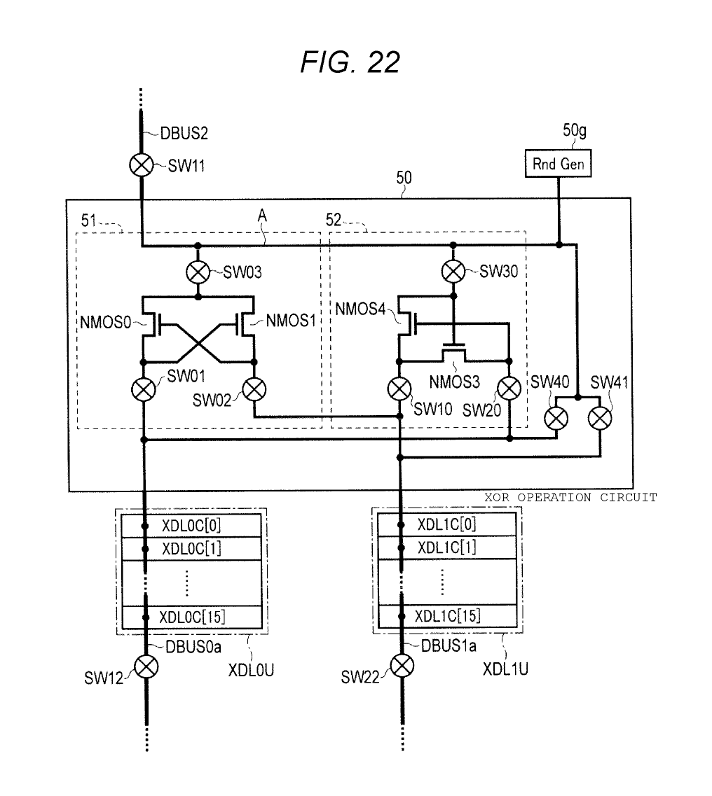

The XOR operation circuit 50 has the configuration illustrated in, for example, FIG. 22. FIG. 22 illustrates elements and electrical connections of a part of a memory according to the third embodiment. As illustrated in FIG. 22, the XOR operation circuit 50 includes a randomization circuit 51 and a decoding circuit 52.

The randomization circuit 51 includes N type MOSFETs NMOS0 and NMOS1, and switches SW01, SW02, and SW03. The switches SW01, SW02, and SW03 are, for example, MOSFETs. Ends of each of the transistors NMOS0 and NMOS1 are connected to a node A via the switch SW03. The node A is connected to the bus DBUS2 via the switch SW11. The other end of the transistor NMOS0 is connected to a data bus DBUS0a via the switch SW01, and is connected to a gate of the transistor NMOS1. The other end of the transistor NMOS1 is connected to a data bus DBUS1a via the switch SW02, and is connected to a gate of the transistor NMOS0.

The decoding circuit 52 includes MOSFETs NMOS3 and NMOS4, and switches SW10, SW20, and SW30. The switches SW10, SW20, and SW30 are, for example, MOSFETs. One end of the transistor NMOS4 is connected to the node A via the switch SW30. The other end of the transistor NMOS4 is connected to a data bus DBUS1a via the switch SW10. A gate of the transistor NMOS4 is connected to the data bus DBUS0 via the switch SW20. The transistor NMOS3 is connected between the other end of the transistor NMOS4 and the gate of the transistor NMOS4. A gate of the transistor NMOS3 is connected to the data bus DBUS2 via the switch SW30.

The switches SW01, SW02, SW03, SW10, SW20, SW30, SW40, and SW41 are controlled by the sequencer 17.

The data bus DBUS0a is connected to the node A via the switch SW40, so as to be able to bypass the randomization circuit 51 and the decoding circuit 52. In the same manner, the data bus DBUS1a is connected to the node A via the switch SW41, so as to be able to bypass the randomization circuit 51 and the decoding circuit 52.

The random number seed generating unit 50g is connected to the node A.

### 3-2. Operation

First of all, an operation of the XOR operation circuit 50 will be described prior to description of an operation of the memory system 1.

There is a case in which randomization of a sequence of bits is performed for the write data, which is received by the memory 100, from the controller 200, in order to relax uneven distributions of bits of “1” and bits of “0” of a bit string of the data. By relaxing the uneven distributions, reliability of the write data is increased. The randomization is performed with using the randomization circuit 51.

The randomized write data is stored in the data latch XDL1. In order to randomize, the sequencer 17 turns on the switch SW03, turns off the switch SW30, and stores random number seeds from the random number seed generating unit 50g in the data latch XDL0 by controlling the random number seed generating unit 50g. For example, the random number seed includes a bit string of the number equal to the number of bits of one page. The random number seeds are arranged in the order in which bits of “1” and “0” in the bit string are randomly determined. Thus, a value (“0” or “1” of data) of one bit is stored to arrangement which is randomly determined, in each of the data latch circuits XDL0C[0] to XDL0C[15].

Hereinafter, the configuration illustrated in FIG. 22 will be described. However, an operation of the following description is also performed in parallel in the portions which have the same configurations as in FIG. 22 and are different from FIG. 22.

During randomization, the switches SW10, SW20, SW30, SW40, and SW41 are maintained to be off, the switch SW11 is maintained to be on. In addition, at a time point of the start of the randomization, the switch SW01, SW02, and SW03 are turned off.

The sequencer 17 repeatedly performs an operation with respect to one bit of the write data with respect to each of 16 bits, and performs the operation with respect to 16 bits which are processed by the configuration of FIG. 21, which will be described below. A sequence of the processing of 16 bits is arbitrary. The sequencer 17 performs randomization, using, for example, the data latch circuits LDLC[0] to LDLC[15]. During the randomization, the data latch circuits UDLC[0] to UDLC[15] and LDLC[0] to LDLC[15] are electrically disconnected from the data buses LBUS[0] to LBUS[15].

First of all, the sequencer 17 electrically decouples the data latch circuit LDLC [n] from the data bus LBUS[n]. Subsequently, the sequencer 17 precharges a potential of the data bus DBUS2 to a high level. The high level of the potential of the data bus DBUS2 relates to “1” data.

The sequencer 17 couples the data latch circuit XDL0C[0] to the data bus DBUS0a, and couples the data latch circuit XDL1C[0] to the data bus DBUS1a. As a result, a potential of the data bus DBUS0a is maintained to have a low level in accordance with the data of the data latch circuit XDL1C[0], but is raised to a high level. In addition, a potential of the data bus DBUS1a is maintained to have a low level in accordance with the data of the data latch circuit XDL0C[0], but is raised to a high level. Both the data latch circuits XDLC[0] and XDLC[1] store, for example, “0” data, and thus both the data buses DBUS0a and DBUS1a are maintained to have a low level.

In this state, the sequencer 17 turns on the switches SW01, SW02, and SW03, thereby enabling the randomization circuit 51. As a result, the data bus DBUS2 is maintained to be at a high level or falls to a low level, according to the state of the data buses DBUS0a and DBUS1a. In the present example, the transistor NMOS0 and NMOS1 are maintained to be off, and thus the data bus DBUS2 is maintained to be at a high level.

Subsequently, the sequencer 17 couples the data latch circuit LDLC[0] to the data bus DBUS2. As a result, “1” data is stored in the data latch circuit LDLC[0]. Accordingly, the data stored in the data latch circuit LDLC[0] is inverted data of an exclusive logical sum of the data of the data latch circuit XDL1C and the data of the data latch circuit XDL0C.

When the two the data latch circuits XDL0C[n] and XDL1C[n] store “1” data, the transistors NMOS1 and NMOS2 are turned on. As a result, the data bus DBUS2 is connected to the data buses DBUS0a and DBUS1a, but is maintained to be at a high level. Thus, “1” data is stored in the corresponding data latch circuit LDLC[n].

Meanwhile, when the data latch circuit XDL0C[n] stores “0” data and the data latch circuit XDL1C[n] stores “1” data, the transistor NMOS0 is turned on and the transistor NMOS1 is turned off. As a result, the data bus DBUS2 is connected to the data bus DBUS0a, and falls to a low level. Thus, “1” data is stored in the corresponding data latch circuit LDLC[n]. Even when the data latch circuit XDL0C[n] stores “1” data and the data latch circuit XDL1C[n] stores “0” data, “1” data is stored in the corresponding data latch circuit LDLC[n].

Storing the exclusive logical sum of the data of the data latch circuit XDL0C[y] (y is “0” or a natural number equal to or less than 15) and the data of the data latch circuit XDL1C [y] in the data latch circuit LDLC[y] is performed with respect to each of “0” to “15” of y. Accordingly, the data stored in the data latch circuits LDLC[0] to LDLC[15] is data in which a sequence of bits of a part of the write data stored in the data latch circuits XDLC[0] to XDLC[15] is randomized.

Meanwhile, the data which is read from the cell transistors MT is decoded using the decoding circuit 52. In the following description, the configuration illustrated in FIG. 22 will be described in the same manner as the description with regard to the randomization. However, the operation described below is performed also in the portions which have the same configurations as in FIG. 22 and are different from FIG. 22.

During decoding, the switches SW10, SW20, SW30, and SW11 are maintained to be on, and the switches SW01, SW02, SW03, SW40, and SW41 are maintained to be off.

First of all, the data with an amount of one page which is read from the cell transistors MT is stored in the data latch LDL. Subsequently, the sequencer 17 turns off the switch SW03, turns on the switch SW30, and stores the random number seeds from the random number seed generating unit 50g in the data latch XDL0 by controlling the random number seed generating unit 50g. The random number seed is the same as that to be used at the time of randomizing, and each bit of the random number seed is stored in each of the data latch circuits XDL0C[0] to XDL0C[15]. At a time point of the start of the decoding, any data latch circuit XDL1C of the data latches XDL1 also stores “1” data.

In the same manner as the randomization, the sequencer 17 repeatedly performs the operation of one bit of the write data with respect to each of 16 bits, and performs the operation with respect to 16 bits which are processed by the configuration of FIG. 21, which will be described below.

When the data latch circuit LDLC[y] stores “1” data and the data latch circuit XDL0C[y] stores “1” data, “1” data is continuously stored in the data latch circuit XDL1C[y]. When the data latch circuit LDLC[y] stores “1” data and the data latch circuit XDL0C[y] stores “0” data, “0” data is stored in the data latch circuit XDL1C[y]. When the data latch circuit LDLC[y] stores “0” data and the data latch circuit XDL0C[y] stores “1” data, “0” data is stored in the data latch circuit XDL1C[y]. When the data latch circuit LDLC[y] stores “0” data and the data latch circuit XDL0C[y] stores “0” data, “1” data is continuously stored in the data latch circuit XDL1C[y].

Storing the exclusive logical sum of the data of the data latch circuit XDL1C[y] and the data of the data latch circuit XDL0C[y] in the data latch circuit LDLC[y] is performed with respect to each of “0” to “15” of y. As a result, the data which is read from the cell transistors MT of a read source and whose randomization is released is stored in the data latch XDL0.

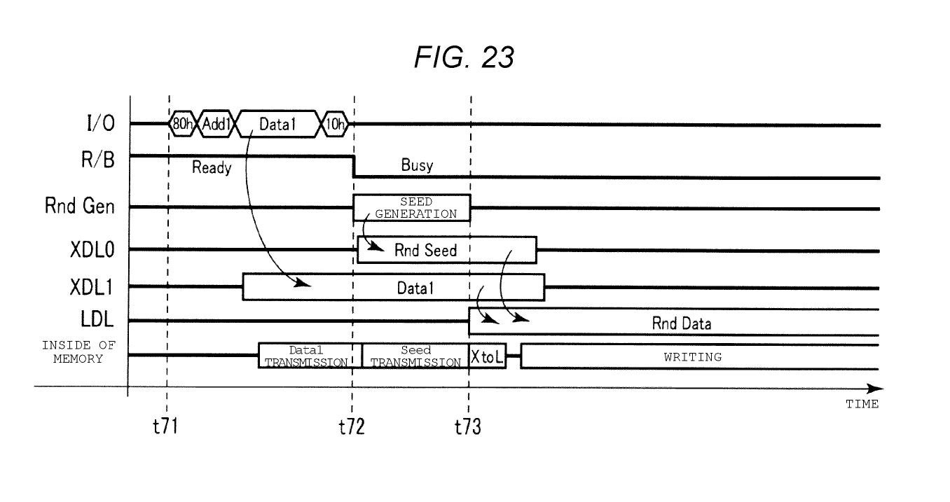

Next, an example of the operation of the memory system 1 will be described with reference to FIG. 23. FIG. 23 illustrates a timing chart at the time of writing of the memory system 1 according to the third embodiment.

As illustrated in FIG. 23, the controller 200 transmits the write command 80h, the address signal Add1, and the write data Data1 to the memory 100 from time t71. The address signal Add1 designates a write destination. When the memory 100 receives the data Data1, the data Data1 is stored in the data latch XDL1, and is continuously stored thereafter.

When the memory 100 receives a write start command 10, the sequencer 17 generates the random number seed by controlling the random number seed generating unit 50g, from time t72. The random number seed is transmitted to the data latch XDL0, is stored in the data latch XDL0, and is continuously stored thereafter.

When transmission of the random number seed to the data latch XDL0 is completed, the sequencer 17 randomizes bit positions of the data Data1 using the random number seed from time t73, and transmits the randomized data Data1 to the data latch LDL. Subsequently, the sequencer 17 writes the data of the data latch LDL to the designated cell transistors MT.

### 3-3. Effect (Advantage)

According to the third embodiment, the memory 100 includes the two data latches XDL0 and XDL1 which are connected to the data bus IOBUS, in the same manner as in the second embodiment. For this reason, the same advantages as those of the second embodiment are obtained.

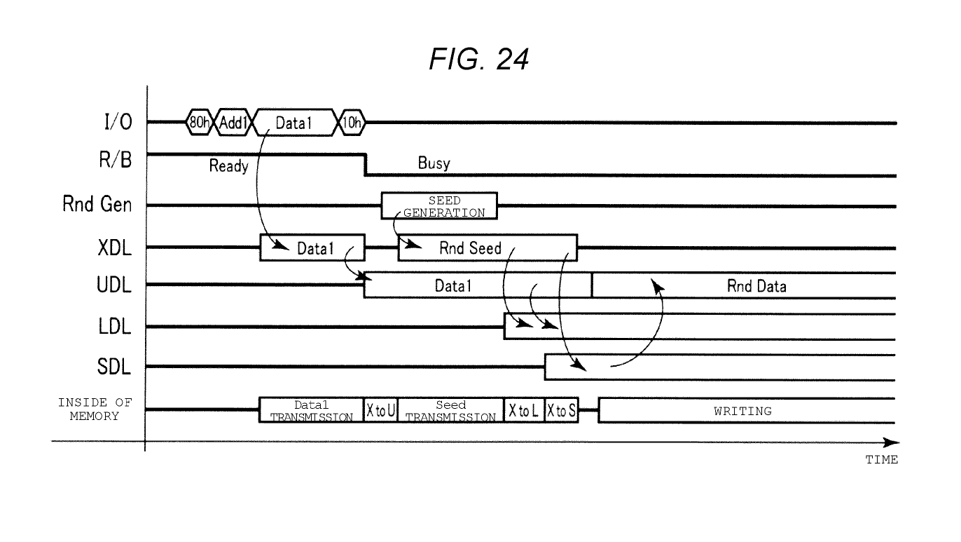

Furthermore, according to the third embodiment, the following advantages are obtained. First of all, for comparison, an example of writing accompanied by randomization in the memory having only one data latch (for example data latch XDL) for input/output will be described with reference to FIG. 24.

As illustrated in FIG. 24, when the data latch XDL completes reception of the write data Data1, the sequencer transmits the data Data1 to the data latch UDL thereby releasing the data latch XDL. When the data latch XDL is released, the sequencer transmits the random number seed to the data latch XDL. Subsequently, the sequencer performs calculation of a logical product of an inverted bit of each bit of the bit string of the random number seed and a corresponding bit of the data Data1, with respect to the entire bits of one page, and transmits the calculation result to the data latch LDL. In addition, the sequencer performs calculation of a logical product of each bit of the random number seed and a corresponding bit of the data Data1, with respect to the entire bits of the data with a size of an amount of one page, and transmits the calculation result to the data latch SDL. Finally, the sequencer performs calculation of a logical sum of the data of the data latch LDL and the data of the data latch SDL, with respect to each bit, and transmits the calculation result to the data latch UDL. The data of the data latch UDL which is thus obtained is an exclusive logical sum of the write data Data1 and the random number seed.

As may be seen from FIG. 24, three transmissions from the data latch XDL to the data latches UDL, LDL, and SDL are required. As described above, the data bus DBUS has a width of one bit, and thus data transmission between the data latch XDL and the data latches SDL and LDL, or UDL requires a long time.

Meanwhile, according to the third embodiment, since the memory 100 includes two data latches XDL0 and XDL1 connected to the data bus IOBUS, the data transmission from the data latch XDL occurs only once from time t73 and thereafter, as may be seen from FIG. 23. For this reason, according to the third embodiment, the time required for the writing accompanying the data randomization is reduced, as compared with that in FIG. 24.

### Other Embodiments

In the first to third embodiments, the following operation and configuration may be used.

(1) In read operations of multi-value levels, a voltage which is applied to a word line selected at a read operation of an A level is between, for example, 0 V and 0.55 V. The embodiments are not limited to this, and the voltage may be any one between 0.1 V and 0.24 V, 0.21 V and 0.31 V, 0.31 V and 0.4 V, 0.4 V and 0.5 V, 0.5 V and 0.55 V, and the like. A voltage which is applied to a word line selected at a read operation of a B level is between, for example, 1.5 V and 2.3 V. The embodiments are not limited to this, and the voltage may be any one between 1.65 V and 1.8 V, 1.8 V and 1.95 V, 1.95 V and 2.1 V, 2.1 V and 2.3 V, and the like. A voltage which is applied to a word line selected at a read operation of a C level is, for example, 3.0 V to 4.0 V. The embodiments are not limited to this, and the voltage may be any one between 3.0 V and 3.2 V, 3.2 V and 3.4 V, 3.4 V and 3.5 V, 3.5 V and 3.6 V, 3.6 V and 4.0 V, and the like. The time (tR) of the read operation may be any one between, for example, 25 μs and 38 μs, 38 μs and 70 μs, 70 μs and 80 μs, and the like.

(2) The write operation includes a program operation and a verification operation. In the write operation, a voltage which is initially applied to a word line selected at the time of program operation is between, for example, 13.7 V and 14.3 V. The embodiments are not limited to this, and the voltage may be any one between, for example, 13.7 V and 14.0 V, 14.0 V and 14.6 V, and the like. A voltage which is initially applied to a word line selected at the time of writing to odd-numbered word lines may be different from a voltage which is initially applied to a word line selected at the time of writing to even-numbered word lines. When the program operation uses an incremental step pulse program (ISPP) method, for example, a voltage of approximately 0.5 V may be used as a step-up voltage. For example, a voltage of 6.0 V to 7.3 V may be used as a voltage which is applied to a non-selected word line. The embodiments are not limited to this, and the voltage may be any one between, for example, 7.3 V and 8.4 V, and may be 6.0 V or less may be used. Pass voltages to be applied may vary depending on whether the non-selected word line is an odd-numbered word line or an even-numbered word line. Any one between, for example, 1,700 μs and 1,800 μs, 1,800 μs and 1,900 μs, and 1,900 μs and 2,000 μs may be used as the time (tProg) of the write operation.

(3) In an erase operation, a voltage that is initially applied to a well which is arranged on an upper portion of a semiconductor substrate and in which memory cells are arranged on an upper side is between, for example, 12V and 13.6 V. The embodiments are not limited to this, and the voltage may be any one between, for example, 13.6 V and 14.8 V, 14.8 V and 19.0 V, 19.0 V and 19.8 V, 19.8 V and 21 V, and the like. Any one between, for example, 3,000 μs and 4,000 μs, 4,000 μs and 5,000 μs, and 5,000 μs and 9,000 μs may be used as the time (tErase) of the erase operation.

(4) the memory cell may have the following configuration. The memory cell includes a charge accumulation film which is arranged on a semiconductor substrate of a silicon substrate or the like via a tunnel insulating film with a thickness of 4 nm to 10 nm. The charge accumulation film may have a stacked structure of an insulating film, such as a silicon nitride (SiN) film with a thickness of 2 nm to 3 nm or a silicon oxynitride (SiON) film, and a polysilicon (Poly-Si) film with a thickness of 3 nm to 8 nm. A metal such as ruthenium (Ru) may be contained in the polysilicon film. The memory cell has an insulating film on the charge accumulation film. The insulating film includes a silicon oxide (SiO₂) film with thickness of 4 nm to 10 nm which is interposed between, for example, a lower layer High-k film with a thickness of 3 nm to 10 nm and an upper layer High-k film with a thickness of 3 nm to 10 nm. A hafnium oxide (HfO) or the like may be used as a material of the High-k film. In addition, a thickness of the silicon oxide film may be greater than that of the High-k film. A control electrode having a thickness of 30 nm to 70 nm is provided on the insulating film via a film having thickness of 3 nm to 10 nm. Such a film is, for example, a metal oxide film such as tantalum oxide (TaO), a metal nitride film such as tantalum nitride (TaN), or the like. The control electrode may use tungsten (W) or the like. An air gap may be formed between the memory cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell;
a sense amplifier connected to the memory cell;
a first data latch that is connected to the sense amplifier and stores data of the memory cell;
a second data latch that is connected to the sense amplifier and stores data of the memory cell;
a third data latch that is connected to an input/output circuit;
a fourth data latch that is connected to the input/output circuit;
a first data bus of n-bit width that connects the sense amplifier, the first data latch, and the second data latch; and
a second data bus of m-bit width that connects the third data latch and the fourth data latch to the first data bus, where m<n.

2. The device according to claim 1, wherein
m is 1 and each of the sense amplifier, the first data latch, the second data latch, the third data latch, the fourth data latch, and the first data bus has n units, and
an i-th unit of the sense amplifier, an i-th unit of the first data latch, and an i-th unit of the second data latch are connected to each other by an i-th first data bus, and to one of the units of the third data latch and one of the units of the fourth data latch through the i-th first data bus and the second data bus, where i is an integer from 1 to n.

3. The device according to claim 2, wherein m is 2 and the second data bus has two units, the first unit of the second data bus connected to the third data latch and the second unit of the second data bus connected to the fourth data latch.

4. The device according to claim 3, wherein
each of the sense amplifier, the first data latch, the second data latch, the third data latch, the fourth data latch, and the first data bus has n units, and
an i-th unit of the sense amplifier, an i-th unit of the first data latch, and an i-th unit of the second data latch are connected to each other by an i-th first data bus, to one of the units of the third data latch through the i-th first data bus and the first unit of the second data bus, and to one of the units of the fourth data latch through the i-th first data bus and the second unit of the second data bus, where i is an integer from 1 to n.

5. The device according to claim 4, further comprising:
a first switch between the first data bus and the first unit of the second data bus that is turned on to enable data to be transferred through one of the units of the first data bus and the first unit of the second data bus; and
a second switch between the first data bus and the second unit of the second data bus that is turned on to enable data to be transferred through one of the units of the first data bus and the second unit of the second data bus.

6. The device according to claim 5, further comprising:
a third switch between the input/output circuit and the first unit of the second data bus that is turned on to enable data to be transferred between the input/output circuit and the third data latch through the first unit of the second data bus; and
a fourth switch between the input/output circuit and the second unit of the second data bus that is turned on to enable data to be transferred between the input/output circuit and the fourth data latch through the second unit of the second data bus.

7. The device according to claim 1, further comprising:
a third data bus that connects the third data latch to the input/output circuit;
a fourth data bus that connects the fourth data latch to the input/output circuit;
a first switch that is operated to connect the second data bus to one of the third and fourth data buses;
a second switch between the input/output circuit and the third data bus that is turned on to enable data to be transferred between the input/output circuit and the third data latch through the third data bus; and
a third switch between the input/output circuit and the fourth data bus that is turned on to enable data to be transferred between the input/output circuit and the fourth data latch through the fourth data bus.

8. The device according to claim 7, further comprising:
an XOR circuit configured to randomize bit positions of data transferred from the second data bus to one of the third and fourth data buses.

9. A method of performing a write operation in a semiconductor memory device including memory cells, a sense amplifier connected to the memory cells, a first data latch that is connected to the sense amplifier and stores data of the memory cells, a second data latch that is connected to the sense amplifier and stores data of the memory cells, a third data latch that is connected to an input/output circuit, a fourth data latch that is connected to the input/output circuit, a first data bus of n-bit width that connects the sense amplifier, the first data latch, and the second data latch, and a second data bus of m-bit width that connects the third data latch and the fourth data latch to the first data bus, where m<n, said method comprising:
storing write data received from the input/output circuit, in the third data latch and the fourth data latch; and
during one cycle of a charge pump generating voltages required for writing and then recovering the charge pump:
transferring the write data in the third data latch to the first data latch,
transferring the write data in the fourth data latch to the second data latch, and
programming the memory cells using the write data in the first and second data latches.

10. The method of claim 9, wherein the memory cells store multi-bit data.

11. The method according to claim 9, wherein
m is 1 and each of the sense amplifier, the first data latch, the second data latch, the third data latch, the fourth data latch, and the first data bus has n units, and
an i-th unit of the sense amplifier, an i-th unit of the first data latch, and an i-th unit of the second data latch are connected to each other by an i-th first data bus, and to one of the units of the third data latch and one of the units of the fourth data latch through the i-th first data bus and the second data bus, where i is an integer from 1 to n.

12. The method according to claim 9, wherein m is 2 and the second data bus has two units, the first unit of the second data bus connected to the third data latch and the second unit of the second data bus connected to the fourth data latch.

13. The method according to claim 12, wherein
each of the sense amplifier, the first data latch, the second data latch, the third data latch, the fourth data latch, and the first data bus has n units, and
an i-th unit of the sense amplifier, an i-th unit of the first data latch, and an i-th unit of the second data latch are connected to each other by an i-th first data bus, to one of the units of the third data latch through the i-th first data bus and the first unit of the second data bus, and to one of the units of the fourth data latch through the i-th first data bus and the second unit of the second data bus, where i is an integer from 1 to n.

14. The method according to claim 9, further comprising:
a third data bus that connects the third data latch to the input/output circuit;
a fourth data bus that connects the fourth data latch to the input/output circuit;
a first switch that is operated to connect the second data bus to one of the third and fourth data buses;
a second switch between the input/output circuit and the third data bus that is turned on to enable data to be transferred between the input/output circuit and the third data latch through the third data bus; and
a third switch between the input/output circuit and the fourth data bus that is turned on to enable data to be transferred between the input/output circuit and the fourth data latch through the fourth data bus.

15. A method of performing a read operation in a semiconductor memory device including memory cells, a sense amplifier connected to the memory cells, a first data latch that is connected to the sense amplifier and stores data of the memory cells, a second data latch that is connected to the sense amplifier and stores data of the memory cells, a third data latch that is connected to an input/output circuit, a fourth data latch that is connected to the input/output circuit, a first data bus of n-bit width that connects the sense amplifier, the first data latch, and the second data latch, and a second data bus of m-bit width that connects the third data latch and the fourth data latch to the first data bus, where m<n, said method comprising:
during one cycle of a charge pump generating voltages required for reading and then recovering the charge pump:
reading the data from the memory cells into first and second data latches,
transferring the read data in the first data latch to the third data latch, and
transferring the read data in the second data latch to the fourth data latch; and
transferring the read data in the third and fourth data latches to the input/output circuit.

16. The method of claim 15, wherein the memory cells store multi-bit data.

17. The method according to claim 15, wherein
m is 1 and each of the sense amplifier, the first data latch, the second data latch, the third data latch, the fourth data latch, and the first data bus has n units, and
an i-th unit of the sense amplifier, an i-th unit of the first data latch, and an i-th unit of the second data latch are connected to each other by an i-th first data bus, and to one of the units of the third data latch and one of the units of the fourth data latch through the i-th first data bus and the second data bus, where i is an integer from 1 to n.

18. The method according to claim 15, wherein m is 2 and the second data bus has two units, the first unit of the second data bus connected to the third data latch and the second unit of the second data bus connected to the fourth data latch.

19. The method according to claim 18, wherein
each of the sense amplifier, the first data latch, the second data latch, the third data latch, the fourth data latch, and the first data bus has n units, and
an i-th unit of the sense amplifier, an i-th unit of the first data latch, and an i-th unit of the second data latch are connected to each other by an i-th first data bus, to one of the units of the third data latch through the i-th first data bus and the first unit of the second data bus, and to one of the units of the fourth data latch through the i-th first data bus and the second unit of the second data bus, where i is an integer from 1 to n.

20. The method according to claim 15, further comprising:
a third data bus that connects the third data latch to the input/output circuit;
a fourth data bus that connects the fourth data latch to the input/output circuit;
a first switch that is operated to connect the second data bus to one of the third and fourth data buses;
a second switch between the input/output circuit and the third data bus that is turned on to enable data to be transferred between the input/output circuit and the third data latch through the third data bus; and
a third switch between the input/output circuit and the fourth data bus that is turned on to enable data to be transferred between the input/output circuit and the fourth data latch through the fourth data bus.
